(19) United States
(12) Patent Application Publication
(10) Pub. No.: US 2015/0060985 A1
(43) Pub. Date: Mar. 5, 2015

(54) NONVOLATILE SEMICONDUCTOR MEMORY DEVICE AND METHOD FOR MANUFACTURING THE SAME

(71) Applicant: Kabushiki Kaisha Toshiba, Minato-ku (JP)

(72) Inventors: Takashi Kobayashi, Mie-ken (JP); Daina Inoue, Mie-ken (JP); Hideto Takekida, Aichi-ken (JP)

(73) Assignee: Kabushiki Kaisha Toshiba, Minato-ku (JP)

(21) Appl. No.: 14/202,501

(22) Filed: Mar. 10, 2014

(30) Foreign Application Priority Data
Sep. 2, 2013 (JP) 2013-181397

(51) Int. Cl. H01L 29/423; H01L 21/28

(52) U.S. Cl. CPC H01L 29/42324; H01L 29/4234; H01L 21/28273; H01L 21/28282
USPC 257/316; 257/324; 438/382

(57) ABSTRACT

According to one embodiment, nonvolatile semiconductor memory device includes: a semiconductor layer; element regions separated the semiconductor layer, the element regions; and a memory cell including a first gate insulating film, a charge storage layer, a second gate insulating film, and a control gate electrode provided above the element regions, a peripheral region including a resistance element including a resistance element layer provided above the semiconductor layer via a first insulating film, a dummy layer provided on a part of the resistance element layer via a second insulating film, a third insulating film provided on the resistance element layer at a first distance from the dummy layer, a fourth insulating film provided on the semiconductor layer at a second distance from the resistance element layer, and a contact piercing the third insulating film, and connected to the resistance element layer, the first distance being shorter than the second distance.

### CROSS-REFERENCE TO RELATED APPLICATIONS

This application is based upon and claims the benefit of priority from Japanese Patent Application No. 2013-181397, filed on Sep. 2, 2013; the entire contents of which are incorporated herein by reference.

### FIELD

Embodiments described herein relate generally to a nonvolatile semiconductor memory device and a method for the same.

### BACKGROUND

These days, the shrinking of memory cells in NAND flash memories has been progressing; and memory cells have high aspect ratios and the pitch of memory cells is narrow. Hence, in recent NAND flash memories, memory cells may collapse during the processing of the memory cells.

### BRIEF DESCRIPTION OF THE DRAWINGS

FIG. 1 is an example of a schematic plan view showing a memory cell region of a nonvolatile semiconductor memory device according to a first embodiment;

FIG. 2A and FIG. 2B are examples of schematic cross-sectional views showing the memory cell region 100 of the nonvolatile semiconductor memory device according to the first embodiment;

FIG. 3A is an example of a schematic cross-sectional view showing a transistor in the peripheral region of the nonvolatile semiconductor memory device according to the first embodiment, and FIG. 3B is an example of a schematic cross-sectional view showing a resistance element layer in the peripheral region of the nonvolatile semiconductor memory device according to the first embodiment;

FIG. 4A is an example of a schematic plan view showing the transistor in the peripheral region of the nonvolatile semiconductor memory device according to the first embodiment, and FIG. 4B is an example of a schematic plan view showing the resistance element layer in the peripheral region of the nonvolatile semiconductor memory device according to the first embodiment;

FIG. 5A to FIG. 15B are examples of schematic cross-sectional views showing the manufacturing process of the nonvolatile semiconductor memory device according to the first embodiment;

FIG. 16A to FIG. 23B are examples of schematic cross-sectional views showing a manufacturing process of a nonvolatile semiconductor memory device according to a reference example;

FIG. 24A to FIG. 34 are examples of schematic views describing a double patterning process and a loop cut process;

FIG. 35A to FIG. 35B are examples of schematic views showing a manufacturing process of a nonvolatile semiconductor memory device according to a second embodiment, and FIG. 35C is an example of schematic cross-sectional views showing the manufacturing process of the nonvolatile semiconductor memory device according to the second embodiment;

FIG. 36A to FIG. 36B are examples of schematic views showing the manufacturing process of a nonvolatile semiconductor memory device according to the second embodiment, and FIG. 36C is an example of schematic cross-sectional views showing the manufacturing process of the nonvolatile semiconductor memory device according to the second embodiment;

FIG. 37A to FIG. 39B are examples of schematic views showing the manufacturing process of a nonvolatile semiconductor memory device according to the second embodiment;

FIG. 40 is an example of a schematic plan view showing a state where the plurality of control gate electrodes extend in the X-direction;

FIG. 41A to FIG. 41C are examples of schematic cross-sectional views showing the state where the plurality of control gate electrodes 60 extend in the X-direction, and FIG. 41A is a cross section taken along line E-E′ of FIG. 40, FIG. 41B is a cross section taken along line F-F′ of FIG. 40, and FIG. 41C is a cross section taken along line G-G′ of FIG. 40, FIG. 41D is examples of schematic plan view showing the state where the control gate electrodes 60 extend in the X-direction, and FIG. 41E is a cross section taken along line G-G′ of FIG. 40D;

FIG. 42 is an example of a schematic plan view showing the state where the plurality of control gate electrodes extend in the X-direction; and

FIG. 43A to FIG. 43C are examples of schematic cross-sectional views showing the state where the plurality of control gate electrodes 60 extend in the X-direction, and FIG. 43A is a cross section taken along line E-E′ of FIG. 42, FIG. 43B is a cross section taken along line F-F′ of FIG. 42, and FIG. 43C is a cross section taken along line G-G′ of FIG. 42.

### DETAILED DESCRIPTION

In general, according to one embodiment, a nonvolatile semiconductor memory device includes: a semiconductor layer; element regions separated the semiconductor layer in a first direction, the element regions extending in a second direction crossing the first direction; and a memory cell including a first gate insulating film, a charge storage layer, a second gate insulating film, and a control gate electrode provided above the element regions, a peripheral region including a resistance element including a resistance element layer provided above the semiconductor layer via a first insulating film, a dummy layer provided on a part of the resistance element layer via a second insulating film, a third insulating film provided on the resistance element layer at a first distance from the dummy layer, a fourth insulating film provided on the semiconductor layer at a second distance from the resistance element layer, and a contact piercing the third insulating film, and connected to the resistance element layer, the first distance being shorter than the second distance.

Various embodiments will be described hereinafter with reference to the accompanying drawings. In the following description, identical components are marked with the same reference numerals, and a description of components once described is omitted as appropriate.

### First Embodiment

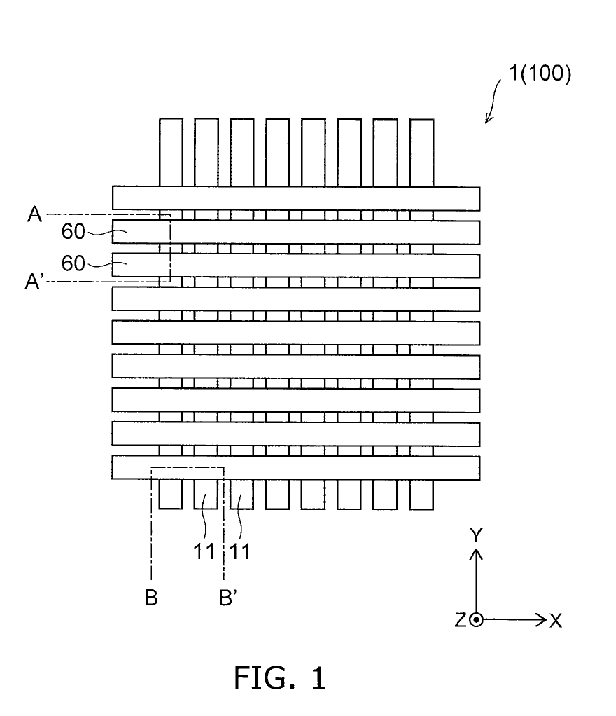

FIG. 1 is an example of a schematic plan view showing a memory cell region of a nonvolatile semiconductor memory device according to a first embodiment.

As shown in FIG. 1, a memory cell region 100 includes element regions 11 (first element regions) and control gate electrodes 60A. The memory cell region 100 is a region where data can be stored, for example. The element regions 11 extend in the Y-direction (a second direction), and are arranged in a direction crossing the Y-direction, for example in the X-direction (a first direction) substantially perpendicular to the Y-direction. The control gate electrodes 60A extend in the X-direction different from the Y-direction, and are arranged in a direction crossing the X-direction, for example in the Y-direction substantially perpendicular to the X-direction.

In a nonvolatile semiconductor memory device 1, the element regions 11 and the control gate electrodes 60A cross each other. The control gate electrodes 60A are provided above the element regions 11.

In the memory cell region 100, a transistor is disposed in a position where the element regions 11 and the control gate electrodes 60A cross each other (described later). The transistors are arranged two-dimensionally in the X-direction and the Y-direction. transistors function as a memory cell of the nonvolatile semiconductor memory device 1. The control gate electrode 60A may be referred to as a word line.

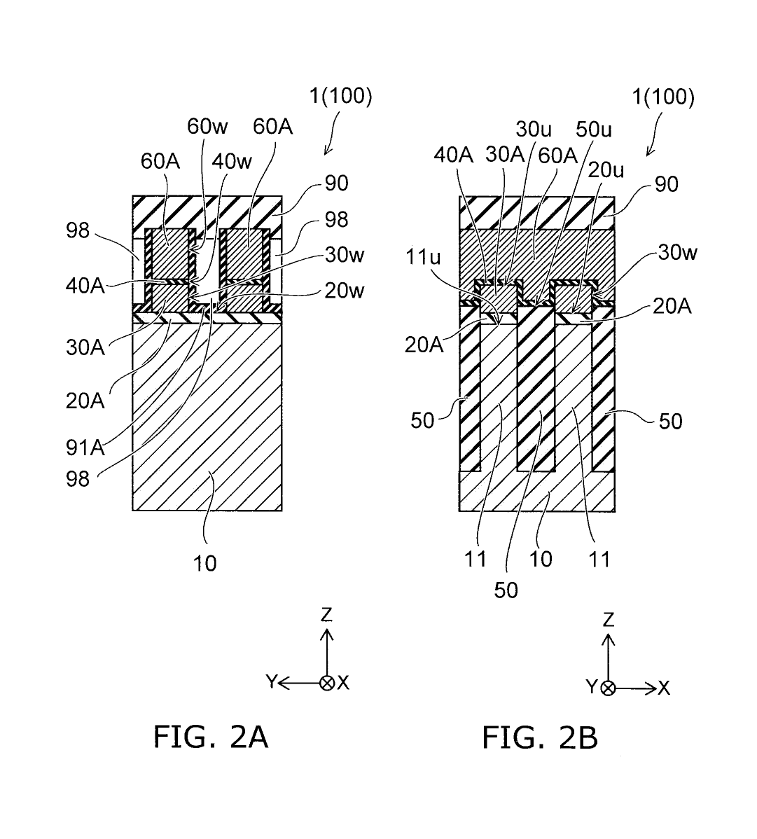

FIG. 2A and FIG. 2B are examples of schematic cross-sectional views showing the memory cell region 100 of the nonvolatile semiconductor memory device according to the first embodiment. FIG. 2A shows a cross section in the position of line A-A′ of FIG. 1, and FIG. 2B shows a cross section in the position of line B-B′ of FIG. 1.

Element regions 11, an upper portion of the semiconductor layer 10 is separated in the X-direction, extend in the Y-direction crossing the X-direction. A gate insulating film 20A (a first gate insulating film), a charge storage layer 30A, a gate insulating film 40A (a second gate insulating film), and the control gate electrode 60A are provided above the element regions 11.

The nonvolatile semiconductor memory device 1 includes a transistor that includes the element region 11, the gate insulating film 20A, the charge storage layer 30A, the gate insulating film 40A, and the control gate electrode 60A in a position where the element region 11 and the control gate electrode 60A cross each other. The charge storage layer 30A may be an insulating film having a trap level, or a stacked film of a conductive film and an insulating film having a trap level.

An upper portion of each of the element regions 11 is doped with an impurity, and functions as an active area that is a part of the transistor of the nonvolatile semiconductor memory device 1.

The gate insulating film 20A is provided between the charge storage layer 30A and each of the plurality of element regions 11. The position of the upper surface 20u of the gate insulating film 20A is lower than the position of the upper surface 50u of an element isolation region 50. The gate insulating film 20A functions as a tunnel insulating film that allows a charge (e.g. electrons) to tunnel between the element region 11 and the charge storage layer 30A.

The charge storage layer 30A is provided in a position where the element regions 11 and the control gate electrodes 60A cross each other. The charge storage layer 30A can store a charge that has tunneled from the element region 11 via the gate insulating film 20A. The charge storage layer 30A may be referred to as a floating gate layer. The charge storage layer 30A is substantially a rectangle extending in the Z-direction in the A-A′ cross section and the B-B′ cross section shown in FIGS. 2A and 2B. The charge storage layer 30A extends substantially in a prism shape in the Z-direction.

The gate insulating film 40A is provided between the charge storage layer 30A and the control gate electrodes 60A. The gate insulating film 40A covers the upper surface 30u of the charge storage layer 30A. For example, in the X-direction, the gate insulating film 40A covers portions of the charge storage layer 30A other than the portion where the element isolation region 50 is in contact with the charge storage layer 30A. In other words, in the X-direction, the gate insulating film 40A covers part of the side surface 30w of the charge storage layer 30A. In the X-direction, the side surface 30w of the charge storage layer 30A is covered with an interlayer insulating film 90.

The upper surface 30u and the side surface 30w of the charge storage layer 30A are covered with the gate insulating film 40A, and the charge stored in the charge storage layer 30A is less likely to leak to the control gate electrode 60A. The gate insulating film 40A may be referred to as a charge block layer.

The element isolation region 50 is provided between element regions 11. The element isolation region 50 is in contact with the gate insulating film 20A and the charge storage layer 30A. The position of the upper surface 11u of the element region 11 is lower than the position of the upper surface 50u of the element isolation region 50.

The control gate electrode 60A covers part of the charge storage layer 30A via the gate insulating film 40A. For example, in the Y-direction, the control gate electrode 60A covers the upper surface 30u and part of the side surface 30w of the charge storage layer 30A via the gate insulating film 40A. In the X-direction, the control gate electrode 60A covers the upper surface 30u of the charge storage layer 30A via the gate insulating film 40A. The control gate electrode 60A functions as a gate electrode for controlling the transistor.

The interlayer insulating film 90 is provided on the control gate electrode 60A. In the Y-direction, an insulating film 91A is provided on the side surface 60w of the control gate electrode 60A, the side surface 40w of the gate insulating film 40A, the side surface 30w of the charge storage layer 30A, and the upper surface 20u of the gate insulating film 20A. In the Y-direction, the portion surrounded by the interlayer insulating film 90 and the insulating film 91A is a space 98.

The nonvolatile semiconductor memory device 1 has a peripheral region in addition to the memory cell region 100.

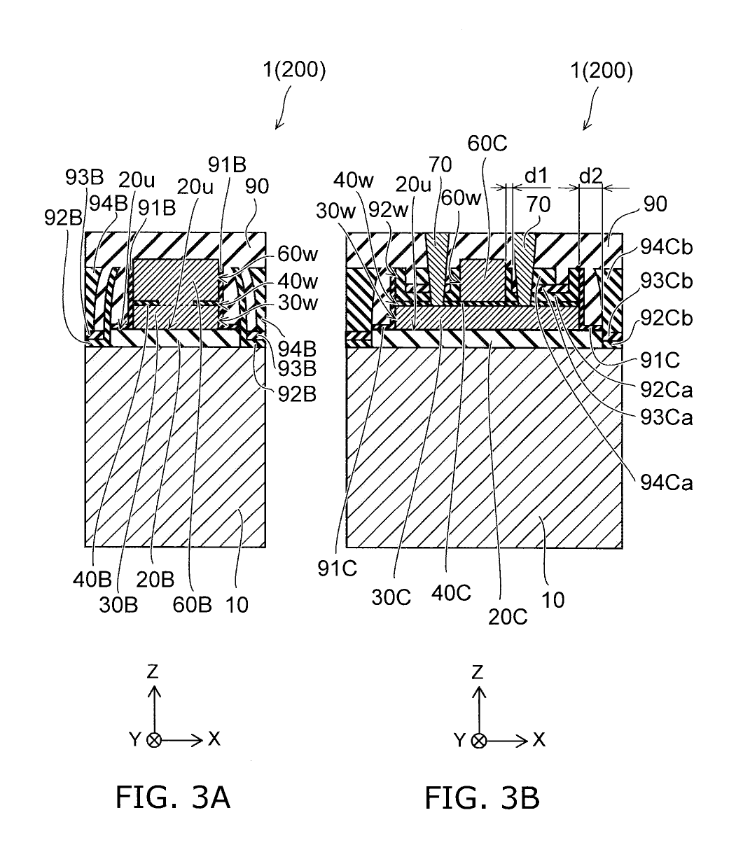

FIG. 3A is an example of a schematic cross-sectional view showing a transistor in the peripheral region of the nonvolatile semiconductor memory device according to the first embodiment, and FIG. 3B is an example of a schematic cross-sectional view showing a resistance element layer in the peripheral region of the nonvolatile semiconductor memory device according to the first embodiment.

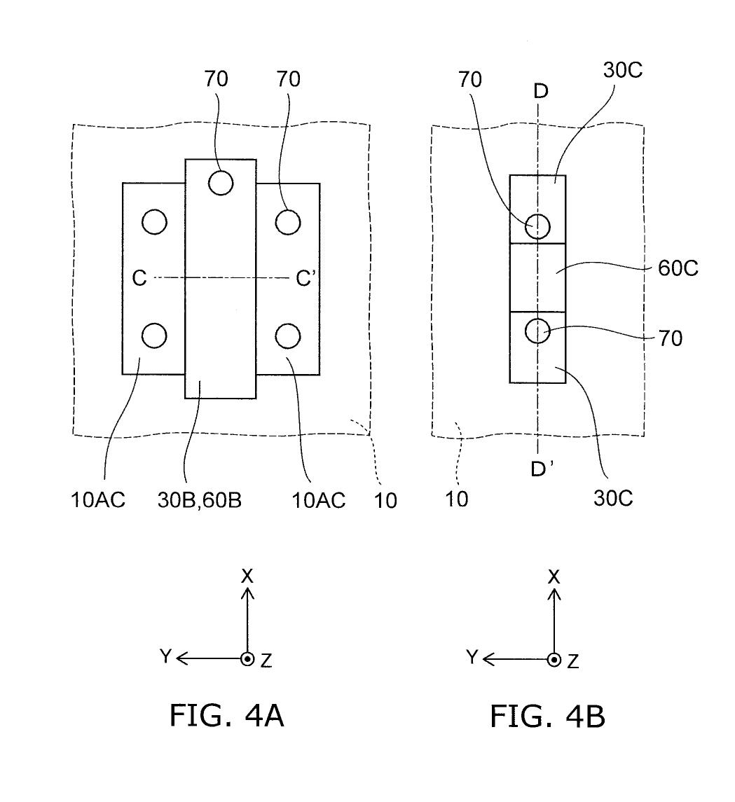

FIG. 4A is an example of a schematic plan view showing the transistor in the peripheral region of the nonvolatile semiconductor memory device according to the first embodiment, and FIG. 4B is an example of a schematic plan view showing the resistance element layer in the peripheral region of the nonvolatile semiconductor memory device according to the first embodiment.

FIG. 3A and FIG. 4A show a three-dimensional coordinate system showing the X-direction, the Y-direction perpendicular to the X-direction, and the Z-direction perpendicular to the X-direction and the Y-direction.

The C-C′ cross section of FIG. 4A corresponds to FIG. 3A. The D-D′ cross section of FIG. 4B corresponds to FIG. 3B. FIG. 4A and FIG. 4B do not show the interlayer insulating film 90 shown in FIG. 3A and FIG. 3B for the sake of convenience.

A peripheral region 200 may be provided on the outside of the memory cell region 100. In the peripheral region 200, a logic circuit including a transistor, a resistance element, and the like etc. are provided. The logic circuit etc. can control the memory cell during a write operation or a read operation.

FIG. 3A shows a cross section of the transistor. As shown in FIG. 3A, the peripheral region 200 includes a transistor that includes the semiconductor layer 10, a gate insulating film 20B, and gate electrodes 30B and 60B. Such a transistor may be provided in plural in the peripheral region 200. In the peripheral region 200, the gate insulating film 20B is provided above the semiconductor layer 10. The gate electrode 30B is provided above the gate insulating film 20B. An insulating film 40B is provided on the gate electrode 30B. The gate electrode 60B is provided on the insulating film 40B. At least part of the insulating film 40B has opened, and the gate electrode 60B and the gate electrode 30B are electrically connected each other.

The gate electrodes 30B and 60B are provided on an element region 10AC. An insulating film 91B is provided on the side surface 60w of the gate electrode 60B, the side surface 40w of the insulating film 40B, the side surface 30w of the gate electrode 30B, and the upper surface 20u of the gate insulating film 20B.

An insulating film 92B is provided on the semiconductor layer 10. The insulating film 92B has a portion in contact with the semiconductor layer 10 and a portion extending in the direction from the gate electrode 30B toward the gate electrode 60B. An insulating film 93B is provided on the insulating film 92B. An insulating film 94B is provided on the insulating film 93B.

The interlayer insulating film 90 is provided on the gate electrode 60B, between the insulating film 91B and the insulating film 92B, between the insulating film 92B and the insulating film 94B, and on the insulating film 94B.

As shown in FIG. 3B, in the peripheral region 200, a resistance element layer 30C is provided above the semiconductor layer 10 via an insulating film 20C (a first insulating film). An insulating film 40C is provided on the resistance element layer 30C. A conductive layer 60C is provided on part of the resistance element layer 30C via the insulating film 40C (a second insulating film). The conductive layer 60C is a dummy layer. The resistance element layer 30C like this may be provided in plural in the peripheral region 200.

An insulating film 92Ca is provided on portions of the resistance element layer 30C where the conductive layer 60C is not provided, via the insulating film 40c. The insulating film 92Ca is provided such as contacting with the side surface 60w of the conductive layer 60C. An insulating film 93Ca is provided on the insulating film 92Ca. The insulating film 93Ca is provided on the resistance element layer 30C at a distance of d1 (a first distance) from the conductive layer 60C in the X-direction. An insulating film 94Ca is provided on the insulating film 93Ca.

An insulating film 91C is provided on the side surface 92w of the insulating film 92Ca, the side surface 40w of the insulating film 40C, the side surface 30w of the resistance element layer 30C, and the upper surface 20u of the insulating film 20C. An insulating film 92Cb is provided on the semiconductor layer 10. An insulating film 93Cb is provided on the insulating film 92Cb. The insulating film 93Cb (a fourth insulating film) is provided on the semiconductor layer 10 at a distance of d2 (a second distance) from the resistance element layer 30C. The distance d1 is shorter than the distance d2. An insulating film 94Cb is provided on the insulating film 93Cb.

The interlayer insulating film 90 is provided on the conductive layer 60C, on the insulating film 94Ca, on the insulating film 93Ca, on the insulating film 94Cb, and between the insulating film 91C and the insulating film 94Cb.

A pair of contacts 70 are connected to the resistance element layer 30C on both sides of the conductive layer 60C, for example. The contact 70 extends in the direction from the resistance element layer 30C to the conductive layer 60C, and pierces the insulating film 94Ca, the insulating film 93Ca, and the insulating film 92Ca to be connected to the resistance element layer 30C.

The material of the semiconductor layer 10 (or the element region 11) is an n-type semiconductor crystal, for example. The material of the element region 11 is a p-type semiconductor crystal, for example. As the semiconductor crystal is, for example, a silicon (Si) crystal.

The material of the gate insulating films 20A and 20B and the insulating film 20C is silicon oxide (SiO₂), silicon nitride (Si₃N₄), or the like, for example. The gate insulating films 20A, 20B, and 20C may be a single layer of a silicon oxide film or a silicon nitride film, or a film in which either a silicon oxide film or a silicon nitride film is stacked, for example.

The material of the charge storage layer 30A, the gate electrode 30B, and the resistance element layer 30C is a semiconductor containing a p-type impurity, a metal, a metal compound, or the like, for example. As the material of the charge storage layer 30A, the gate electrode 30B, and the resistance element layer 30C, for example, amorphous silicon (a-Si), polysilicon (poly-Si), silicon germanium (SiGe), silicon nitride (SiₓN_{y}), hafnium oxide (HfOₓ), and the like are given.

The gate insulating film 40A, the insulating film 40B, and the insulating film 40C may be a single layer of a silicon oxide film or a silicon nitride film, or a film in which either a silicon oxide film or a silicon nitride film is stacked, for example. For example, the gate insulating film 40A may be what is called an ONO film (silicon oxide film/silicon nitride film/silicon oxide film). The gate insulating film 40A may be also a metal oxide film or a metal nitride film.

The material of the element isolation region 50 and the interlayer insulating film 90 is silicon oxide (SiO₂), for example.

The material of the control gate electrode 60A, the gate electrode 60B, and the conductive layer 60C is a semiconductor containing a p-type impurity, for example. Alternatively, the material of the control gate electrode 60A may be a metal such as tungsten or a metal silicide, for example.

The material of the contact 70 contains a metal such as tungsten, copper, and aluminum, polysilicon, a metal silicide, or the like, for example.

Boron (B) is given as the p-type impurity element, for example. Phosphorus (P) and arsenic (As) are given as the n-type impurity element, for example.

Other than these, in the embodiment, portions written as insulating layers and insulating films contain silicon oxide (SiO₂), silicon nitride (Si₃N₄), or the like, for example. The material of the insulating film 93Ca and the material of the insulating film 93Cb are the same, for example.

The manufacturing process of the nonvolatile semiconductor memory device 1 will now be described.

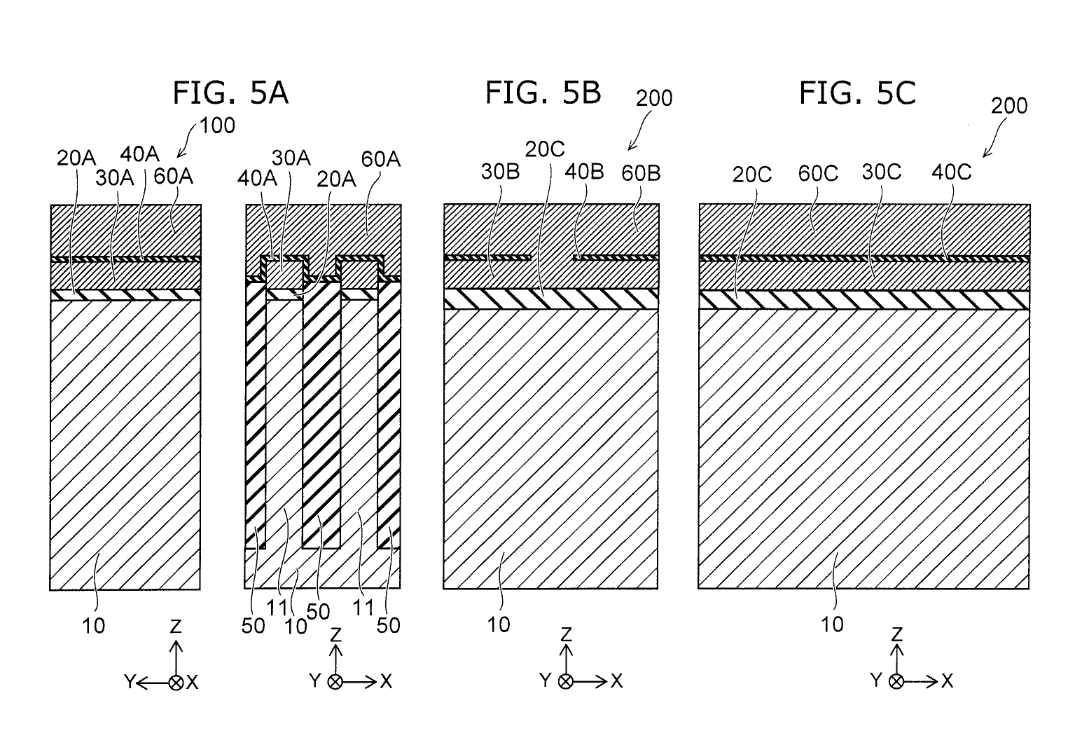

FIG. 5A to FIGS. 15A and 15B examples of are schematic cross-sectional views showing the manufacturing process of the nonvolatile semiconductor memory device according to the first embodiment.

The drawings of the numbers including “A” show the manufacturing process of the memory cell region 100, and the drawings of the numbers including “B” and “C” show the manufacturing process of the peripheral region 200. The drawings of the numbers including “B” show the manufacturing process of the transistor provided in the peripheral region 200. The drawings of the numbers including “C” show the manufacturing process of the resistance element layer provided in the peripheral region 200.

Left figure of FIG. 5A shows a cross section of the structure of the memory cell region 100 taken perpendicular to the X-direction. Right figure of FIG. 5A shows a cross section of the structure of the memory cell region 100 taken perpendicular to the Y-direction. FIG. 5B shows a cross section of the peripheral region in a state before it is processed into the transistor shown in FIG. 3A, and FIG. 5C shows a cross section of the peripheral region in a state before it is processed into the resistance element layer shown in FIG. 3B.

First, as shown in FIG. 5A, in the memory cell region 100, the semiconductor layer 10, the gate insulating film 20A provided above the semiconductor layer 10, the charge storage layer 30A provided above the gate insulating film 20A, the gate insulating film 40A provided on the charge storage layer 30A, and the control gate electrode 60A provided on the gate insulating film 40A are prepared. At this stage, when the control gate electrode 60A is viewed parallel to the Z-direction, the control gate electrode 60A is not divided in the Y-direction and is in a planar form. Here, the control gate electrode 60A in a planar form may be referred to as a control gate electrode layer 60A.

At this stage, the semiconductor layer 10 is separated in the X-direction to form element regions 11 extending in the Y-direction crossing the X-direction (the right figure of FIG. 5B). The gate insulating film 20A provided above each of the element regions 11 and the charge storage layer 30A provided above the gate insulating film 20A and extending in the Y-direction are formed. Further, the gate insulating film 40A provided on each of the charge storage layers 30A and on at least part of the side surface 30w of each of the charge storage layers 30A, and the control gate electrode 60A provided on the gate insulating film 40A are formed. The structure shown in FIG. 5B is the same structure as the structure in which the interlayer insulating film 90 is removed from the structure shown in FIG. 2B.

In the peripheral region 200 shown in FIG. 5B, the gate insulating film 20B provided above the semiconductor layer 10, the gate electrode 30B provided above the gate insulating film 20B, the insulating film 40B provided on the gate electrode 30B, and the gate electrode 60B provided on the insulating film 40B are prepared. At least part of the insulating film 40B has opening, and the gate electrode 60B and the gate electrode 30B are electrically connected each other.

In the peripheral region 200 shown in FIG. 5C, the insulating film 20C provided above the semiconductor layer 10, the resistance element layer 30C provided above the insulating film 20C, the insulating film 40C provided on the resistance element layer 30C, and the conductive layer 60C provided on the insulating film 40C are prepared. In other words, the resistance element layer 30C is formed above the semiconductor layer 10 via the insulating film 20C, and the conductive layer 60C is formed on the resistance element layer 30C via the insulating film 40C.

Here, the gate insulating film 20A, the gate insulating film 20B, and the insulating film 20C are the same material and may be formed simultaneously. The charge storage layer 30A, the gate electrode 30B, and the resistance element layer 30C may be the same material and be formed simultaneously. The gate insulating film 40A, the insulating film 40B, and the insulating film 40C may be the same material and be formed simultaneously. The control gate electrode 60A, the gate electrode 60B, and the conductive layer 60C may be the same material and be formed simultaneously.

The gate insulating film 20A, the gate insulating film 20B, and the insulating film 20C are formed by the thermal oxidation method, for example. The thickness of the gate insulating film 20A, the gate insulating film 20B, and the insulating film 20C is 10 nm (nanometers), for example.

Boron (B) may be introduced into the charge storage layer 30A, the gate electrode 30B, and the resistance element layer 30C. The thickness of the charge storage layer 30A, the gate electrode 30B, and the resistance element layer 30C is 80 nm, for example.

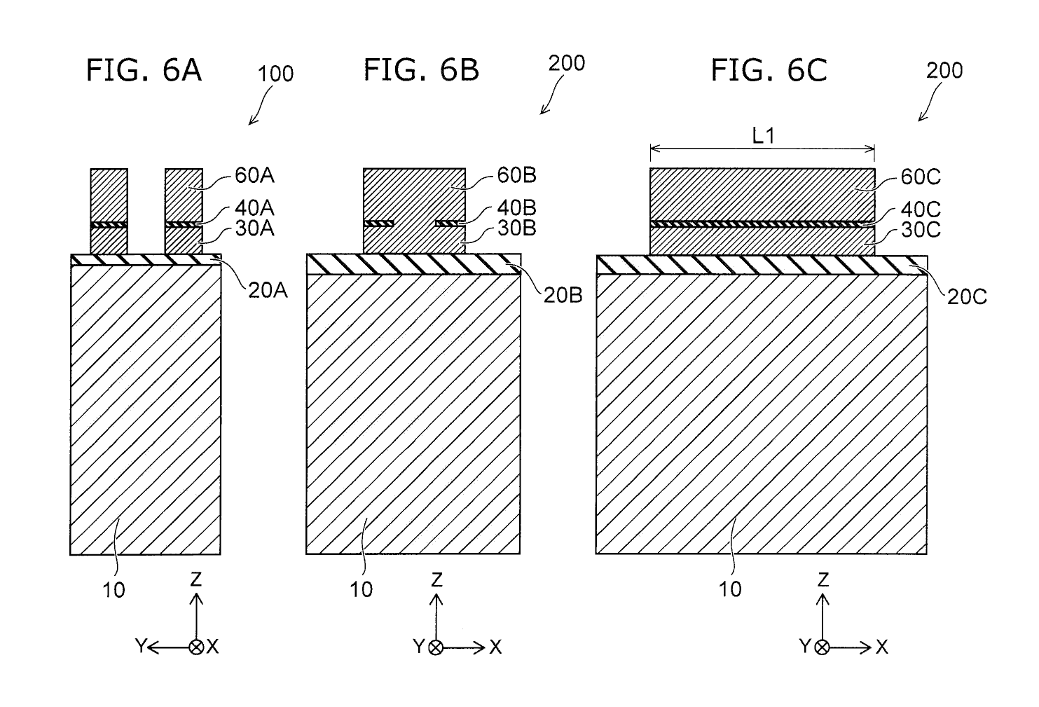

The cross sectional structure of the memory cell region 100 taken perpendicular to the Y-direction maintains the state of right figure of FIG. 5A after this stage. Therefore, after this, the illustration of the state after the state of right figure of FIG. 5A is omitted. FIG. 6A subsequently illustrated shows the state after the state of FIG. 5A, and FIGS. 6B and 6C correspond to FIGS. 5B and 5C, respectively.

Next, as shown in FIG. 6A, in the memory cell region 100, RIE (reactive ion etching) processing is performed on the control gate electrode 60A, the gate insulating film 40A, and the charge storage layer 30A. Thereby, the control gate electrode 60A in a planar form is separated in the Y-direction. In the Y-direction, the charge storage layer 30A, the control gate electrode 60A provided on the charge storage layer 30A, and the gate insulating film 40A sandwiched between the charge storage layer 30A and the control gate electrode 60A are divided. Consequently, the charge storage layer 30A becomes a substantially prism shape. Each of the control gate electrodes 60A extends in the X-direction. The structure including the charge storage layer 30A in a substantially prism shape, the gate insulating film 40A provided on the charge storage layer 30A, and the control gate electrode 60A provided on the charge storage layer 30A via the gate insulating film 40A is referred to as a memory cell.

In the peripheral region 200 shown in FIG. 6B, the gate electrode 30B, the insulating film 40B, and the gate electrode 60B provided on the semiconductor layer 10 are processed by RIE processing.

In the peripheral region 200 shown in FIG. 6C, the resistance element layer 30C, the insulating film 40C, and the conductive layer 60C provided on the semiconductor layer 10 are processed by RIE processing. The processing is performed such that the resistance element layer 30C, the insulating film 40C, and the conductive layer 60C have a length of L1 (a first length) in the X-direction, for example.

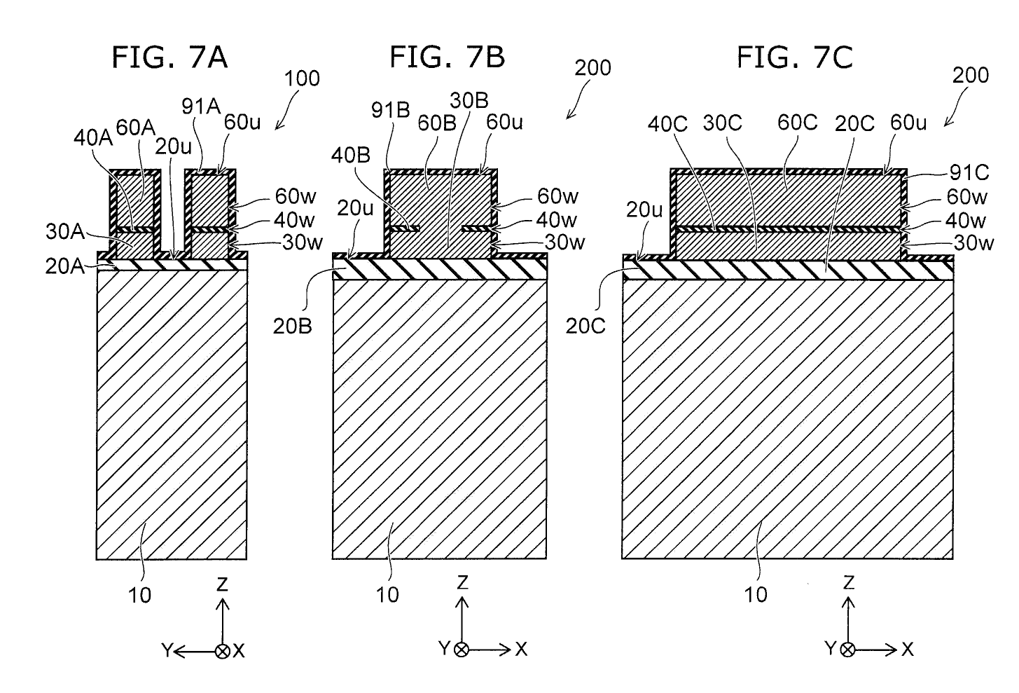

Next, in the memory cell region 100 shown in FIG. 7A, the insulating film 91A is formed on the upper surface 20u of the gate insulating film 20A, the side surface 30w of the charge storage layer 30A, the side surface 40w of the gate insulating film 40A, and the side surface 60w and the upper surface 60u of the control gate electrode 60A.

In the peripheral region 200 shown in FIG. 7B, the insulating film 91B is formed on the upper surface 20u of the gate insulating film 20B, the side surface 30w of the gate electrode 30B, the side surface 40w of the insulating film 40B, and the side surface 60w and the upper surface 60u of the gate electrode 60B.

In the peripheral region 200 shown in FIG. 7C, the insulating film 91C is formed conformally on the upper surface 20u of the insulating film 20C, the side surface 30w of the resistance element layer 30C, the side surface 40w of the insulating film 40C, and the side surface 60w and the upper surface 60u of the conductive layer 60C.

The insulating films 91A, 91B, and 91C are formed simultaneously. The insulating films 91A, 91B, and 91C may be the same material (for example, silicon oxide).

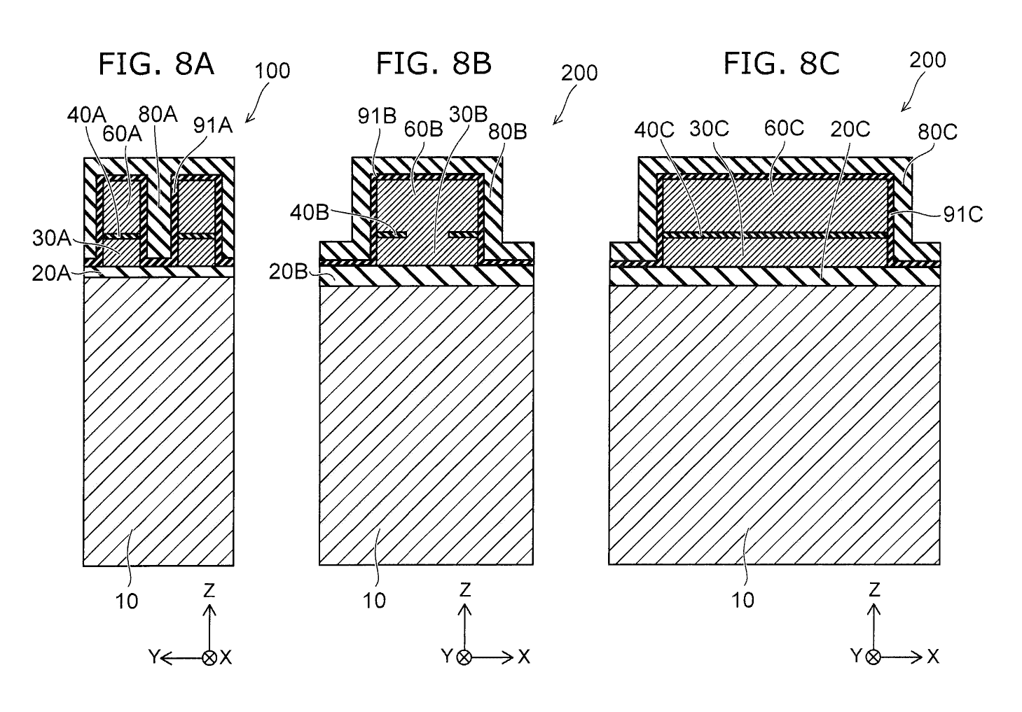

Next, in the memory cell region 100 shown in FIG. 8A, a sacrifice film 80A is formed on the insulating film 91A. In the peripheral region 200 shown in FIG. 8B, a side wall film 80B is formed on the insulating film 91B. In the peripheral region 200 shown in FIG. 8C, a side wall film 80C is formed on the insulating film 91C. Here, in the memory cell region 100, the trench between memory cells is filled with the sacrifice film 80A.

In the peripheral region 200, the portion between adjacent gate electrodes 30B and the portion between adjacent gate electrodes 60B are not filled up with the side wall film 80B.

The sacrifice film 80A and the side wall films 80B and 80C may be formed simultaneously. The sacrifice film 80A and the side wall films 80B and 80C are the same material (for example, silicon nitride).

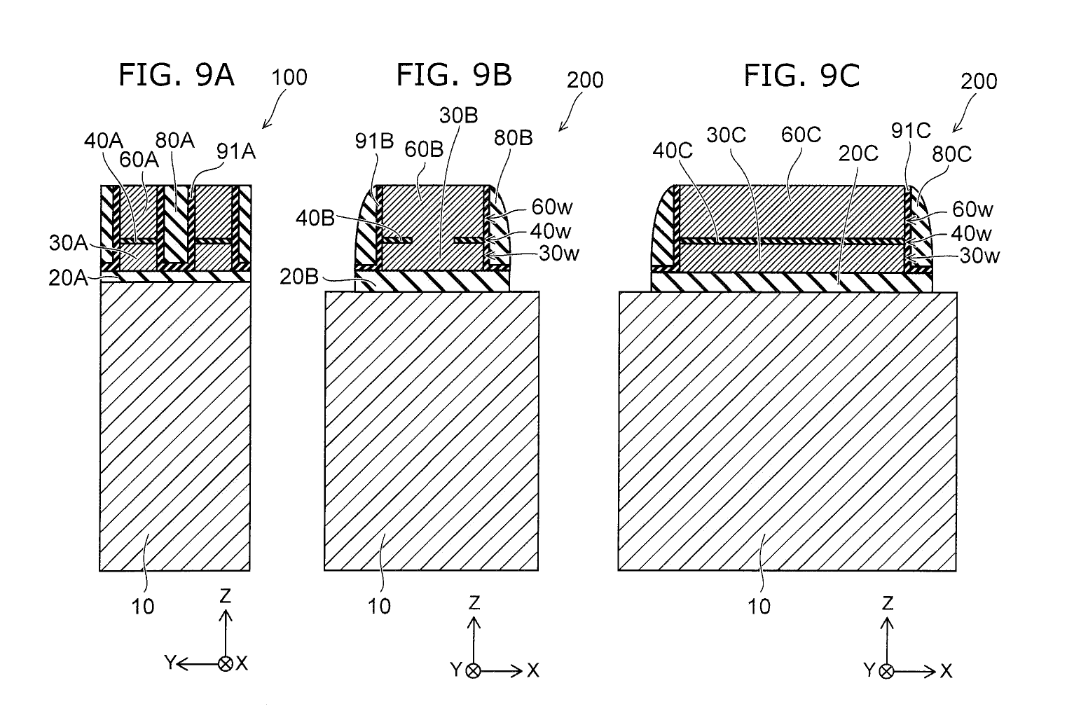

Next, anisotropic etching processing (for example, dry etching processing) is performed on the memory cell region 100 shown in FIG. 9A and the peripheral region 200 shown in FIGS. 9B and 9C, for example.

Thereby, in the memory cell region 100 shown in FIG. 9A, the insulating film 91A and the sacrifice film 80A on the upper side of the control gate electrode 60A are removed. Consequently, the sacrifice film 80A is formed between control gate electrodes 60A and between charge storage layers 30A. The sacrifice film 80A extends in the X-direction.

In the peripheral region 200 shown in FIG. 9B, the side wall film 80B is formed on the side surface 30w of the gate electrode 30B, the side surface 40w of the insulating film 40B, and the side surface 60w of the gate electrode 60B via the insulating film 91B.

In the peripheral region 200 shown in FIG. 9C, the side wall film 80C is formed on the side surface 30w of the resistance element layer 30C, the side surface 40w of the insulating film 40C, and the side surface 60w of the conductive layer 60C via the insulating film 91C.

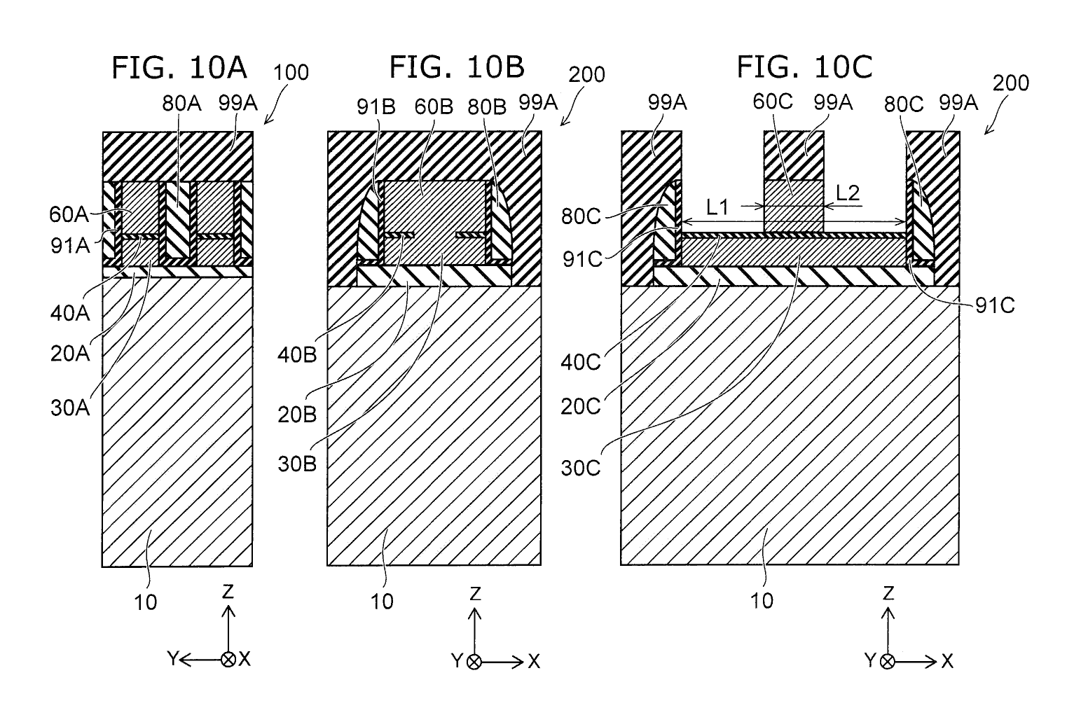

Next, the entire memory cell region 100 shown in FIG. 10A and the entire peripheral region 200 shown in FIGS. 10B and 10C are covered with a mask layer 99A such as a resist, for example. In the peripheral region 200 shown in FIG. 10C, the mask layer 99A is patterned by photolithography technique and etching technique. By the patterning, a mask layer 99A in which both sides of the conductive layer 60c are opened in the X-direction is formed, for example. Subsequently, in the peripheral region 200 shown in FIG. 10C, RIE processing is performed on the conductive layer 60C.

When RIE processing is performed on the conductive layer 60C, because of the mask layer 99A, the memory cell region 100 shown in FIG. 10A and the peripheral region 200 shown in FIG. 10B are not processed. Thereby, portions of the conductive layer 60C provided on the resistance element layer 30C and exposed by the openings are removed. The length of the conductive layer 60C becomes a length of L2 (a second length) shorter than the length L1, for example. After that, the mask layer 99A is removed.

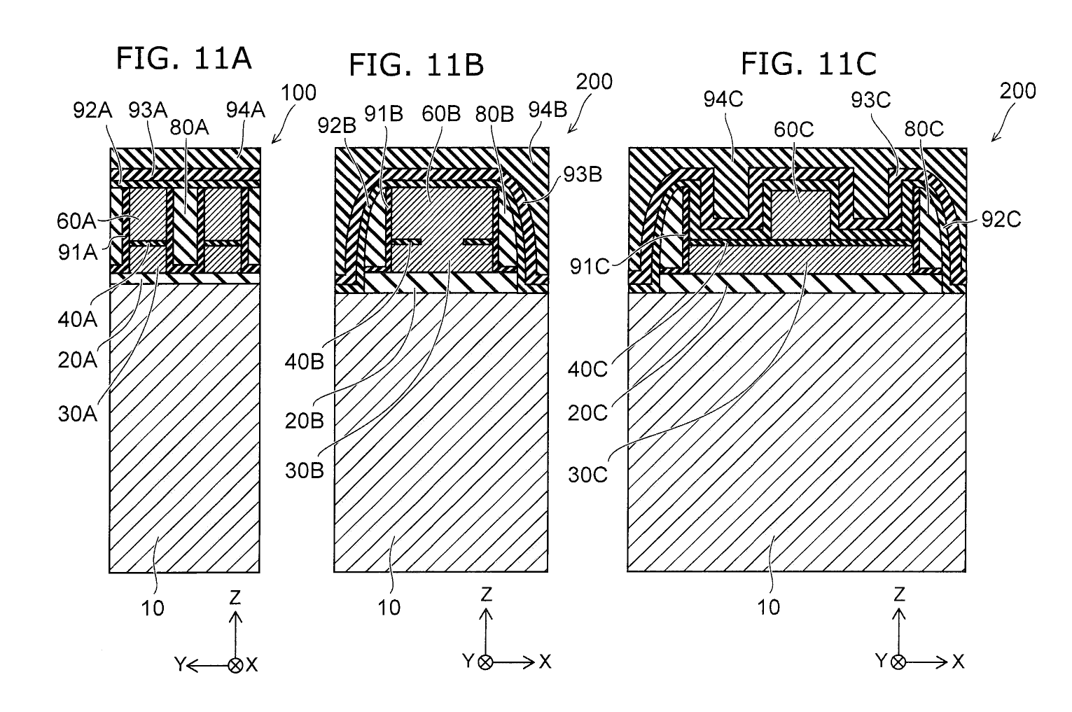

Next, in the memory cell region 100 shown in FIG. 11A, an insulating film 92A is formed on the control gate electrode 60A, on the sacrifice film 80A, and on the insulating film 91A. An insulating film 93A is formed on the insulating film 92A. An insulating film 94A is formed on the insulating film 93A.

In the peripheral region 200 shown in FIG. 11B, the insulating film 92B is formed on the semiconductor layer 10, on the insulating film 91B, on the side wall film 80B, and on the gate electrode 60B. The insulating film 93B is formed on the insulating film 92B. The insulating film 94B is formed on the insulating film 93B. Each of the insulating films 92B and 93B is formed so as to be a thin film lying along the surface of the semiconductor layer 10, the side surface of the gate insulating film 20B, the surface of the side wall film 80B, and the upper surface of the gate electrode 60B, conformably. On the other hand, the insulating film 94B is formed so as to be a thick layer covering the upper side of the semiconductor layer 10, the upper side of the side wall film 80B, and the upper side of the gate electrode 60B.

In the peripheral region 200 shown in FIG. 11C, an insulating film 92C is formed on the semiconductor layer 10, on the insulating film 91C, on the side wall film 80C, on the insulating film 40C, and on the upper surface 60u and the side surface 60w of the conductive layer 60C. An insulating film 93C is formed on the insulating film 92C. An insulating film 94C is formed on the insulating film 93C. Each of the insulating films 92C and 93C is formed so as to be a thin film lying along the surface of the semiconductor layer 10, the side surface of the insulating film 20C, the surface of the side wall film 80C, the surface of the resistance element layer 30C, and the upper surface and the side surface of the conductive layer 60C. On the other hand, the insulating film 94C is formed so as to be a thick layer covering the upper side of the semiconductor layer 10, the upper side of the side wall film 80C, the upper side of the resistance element layer 30C, and the upper side of the conductive layer 60C.

The insulating films 92A, 92B, and 92C may be formed simultaneously. In this case, the insulating films 92A, 92B, and 92C may contain the same material. The material is silicon oxide made by using TEOS (tetraethoxysilane) as the source material, for example. The insulating films 93A, 93B, and 93C may be formed simultaneously. In this case, the insulating films 93A, 93B, and 93C contain the same material (for example, silicon nitride). The insulating films 93A, 93B, and 93C may be a film containing the same material as the sacrifice films 80A, the side wall films 80B, and 80C. The insulating films 94A, 94B, and 94C may be formed simultaneously. In this case, the insulating films 94A, 94B, and 94C contain the same material (for example, NSG (non-doped silicate glass)). Here, the insulating films 92A to 92C and the insulating films 94A to 94C preferably contain a different material from the sacrifice films 80A to 80C and the insulating films 93A to 93C.

Next, the insulating films 93A, 93B, and 93C are used as a stopper film to perform CMP (chemical mechanical polishing) processing on the insulating films 94A, 94B, and 94C. Subsequently, dry etching processing (for example, RIE processing) is performed on the insulating films 92A, 92B, and 92C and the insulating films 93A, 93B, and 93C until the upper surfaces of the control gate electrode 60A, the gate electrode 60B, and the conductive layer 60C are exposed.

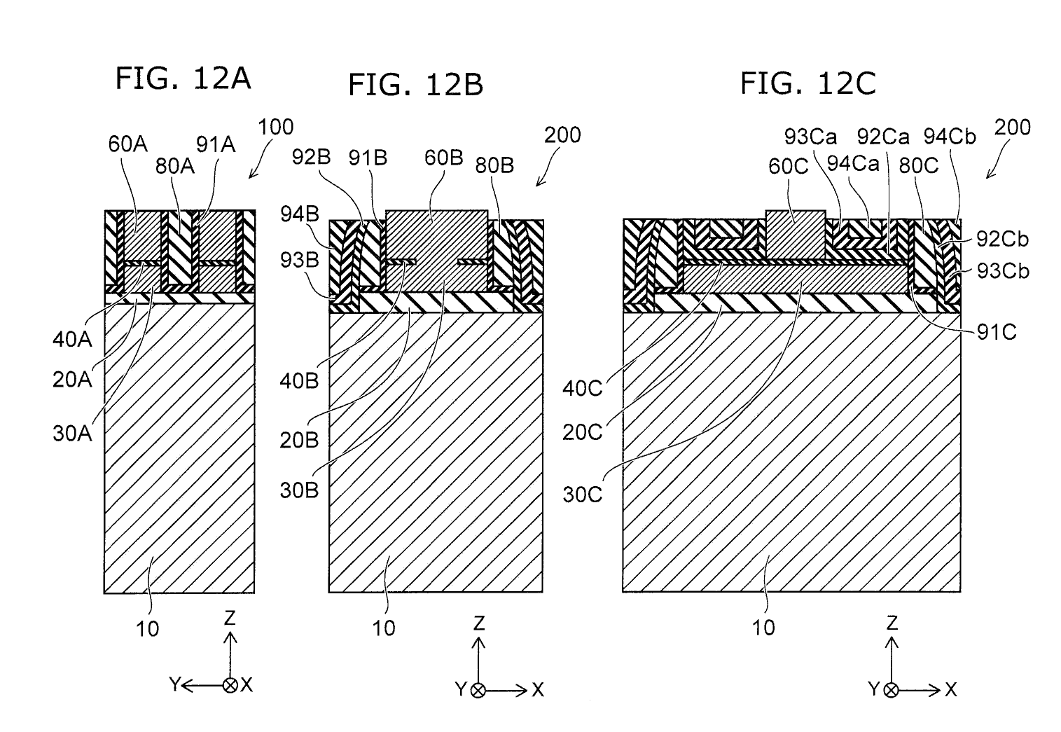

FIG. 12A to FIG. 12C show this state. Here, in the peripheral region 200 shown in FIG. 12C, the insulating film 92Ca and the insulating film 92Cb are films formed such that the insulating film 92C formed on the upper side of an upper portion of the side wall film 80C is removed and the insulating film 92C is separated into two pieces. Here, the insulating film 92Ca is disposed on the resistance element layer 30C, and the insulating film 92Cb is disposed on the side surface of the resistance element 30C. The insulating film 93Ca and the insulating film 93Cb are films formed such that the insulating film 93C formed on the upper side of an upper portion of the side wall film 80C is removed and the insulating film 93C is separated into two pieces. Here, the insulating film 93Ca is disposed on the resistance element layer 30C, and the insulating film 93Cb is disposed on the side surface of the resistance element 30C. The insulating film 94Ca and the insulating film 94Cb are films formed by the insulating film 94C being separated. Here, the insulating film 94Ca is disposed on the resistance element layer 30C, and the insulating film 94Cb is disposed on the side surface of the resistance element 30C.

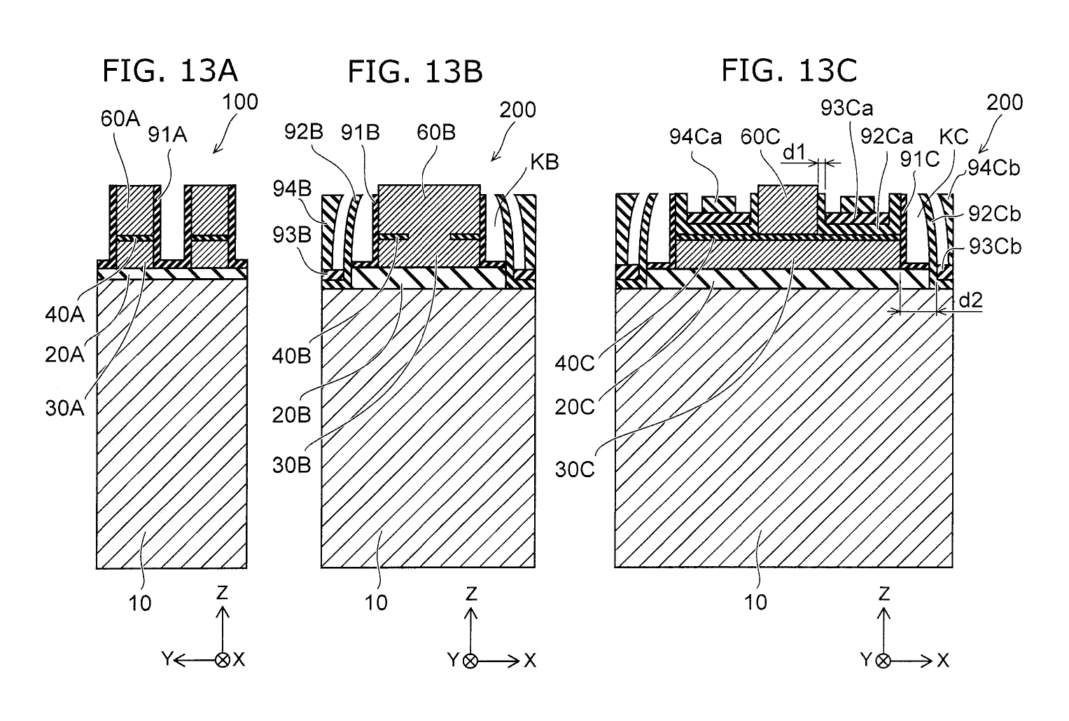

Next, as shown in FIG. 13A to FIG. 13C, wet etching processing is performed on the sacrifice film 80A, the side wall films 80B and 80C, and the insulating films 93B, 93Ca, and 93Cb. A phosphoric acid solution may be used for the wet etching processing, for example.

Thereby, in the memory cell region 100 shown in FIG. 13A, the sacrifice film 80A is removed from between control gate electrodes 60A. In other words, the sacrifice film 80A is removed from between memory cells. In the peripheral region 200 shown in FIG. 13B, the side wall film 80B is removed. Furthermore, part of the insulating film 93B is removed, and the insulating film 93B remains on the insulating film 92B. A space KB is formed between the insulating film 94B and the insulating film 93B and between the insulating film 93B and the insulating film 91B. In the peripheral region 200 shown in FIG. 13C, the side wall film 80C is removed. Furthermore, part of the insulating film 93Ca is removed, and the insulating film 93Ca remains on the insulating film 92Ca. Furthermore, part of the insulating film 93Cb is removed, and the insulating film 93Cb remains on the insulating film 92Cb. A space KC is formed between the insulating film 94Cb and the insulating film 93Cb and between the insulating film 93Cb and the insulating film 91C.

At this stage, in the peripheral region 200 shown in FIG. 13C, the insulating film 93Ca is formed on portions of the resistance element layer 30C where the conductive layer 60C is not provided, at a distance of d1 from the conductive layer 60C. The insulating film 93Cb is formed on the semiconductor layer 10 at a distance of d2 from the resistance element layer 30C. The distance d1 is almost the same as the film thickness of the insulating film 92Ca. The distance d2 is almost the same as the film thickness of the sacrifice film 80C.

Next, the interlayer insulating film 90 is formed in the memory cell region 100 and the peripheral region 200.

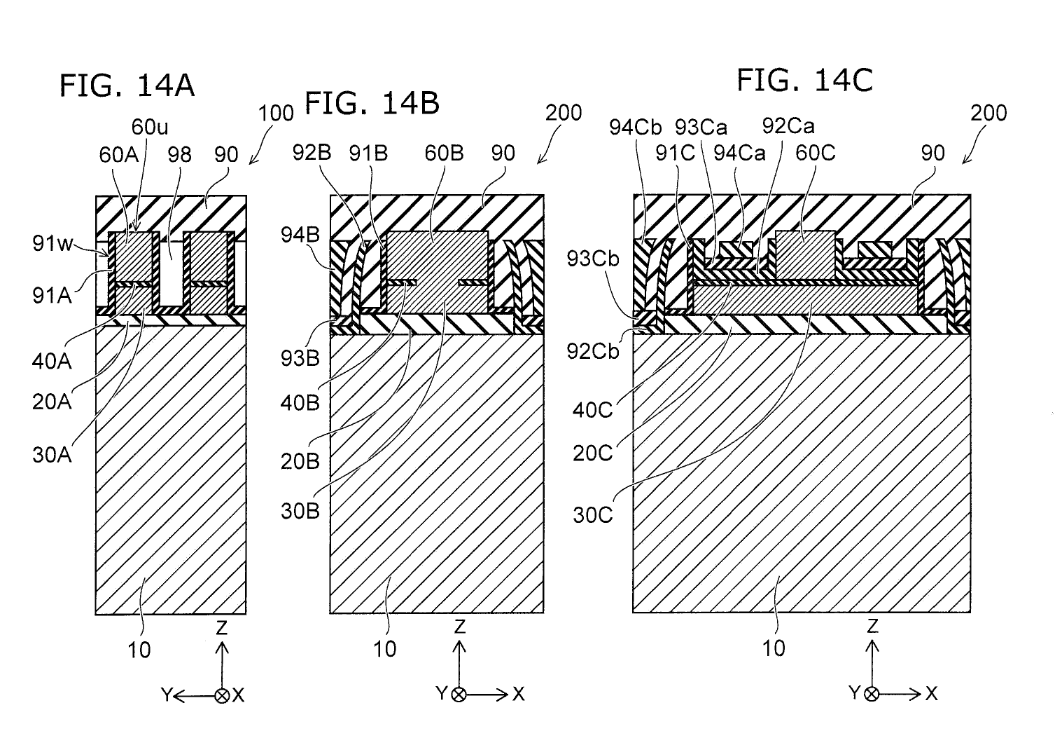

For example, in the memory cell region 100 shown in FIG. 14A, the interlayer insulating film 90 is formed such that a space 98 remains between memory cells. The interlayer insulating film 90 covers the upper surface 60u of the control gate electrode 60A and an upper portion of the side surface 91w of the insulating film 91A.

In the peripheral region 200 shown in FIG. 14B, the interlayer insulating film 90 is formed on the gate electrode 60B, on each of the insulating films 91B, 92B, and 94B, between the insulating film 91B and the insulating film 92B, and between the insulating film 92B and the insulating film 94B. At this time, the space KB may not be filled up with the interlayer insulating film 90, and a space may be formed.

In the peripheral region 200 shown in FIG. 14C, the interlayer insulating film 90 is formed on the conductive layer 60C, on each of the insulating films 91C, 92Ca, 92Cb, 93Ca, 93Cb, 94Ca, and 94Cb, between the insulating film 91C and the insulating film 92Cb, and between the insulating film 92Cb and the insulating film 94Cb. At this time, the space KC may not be filler up with the interlayer insulating film 90, and a space may be formed.

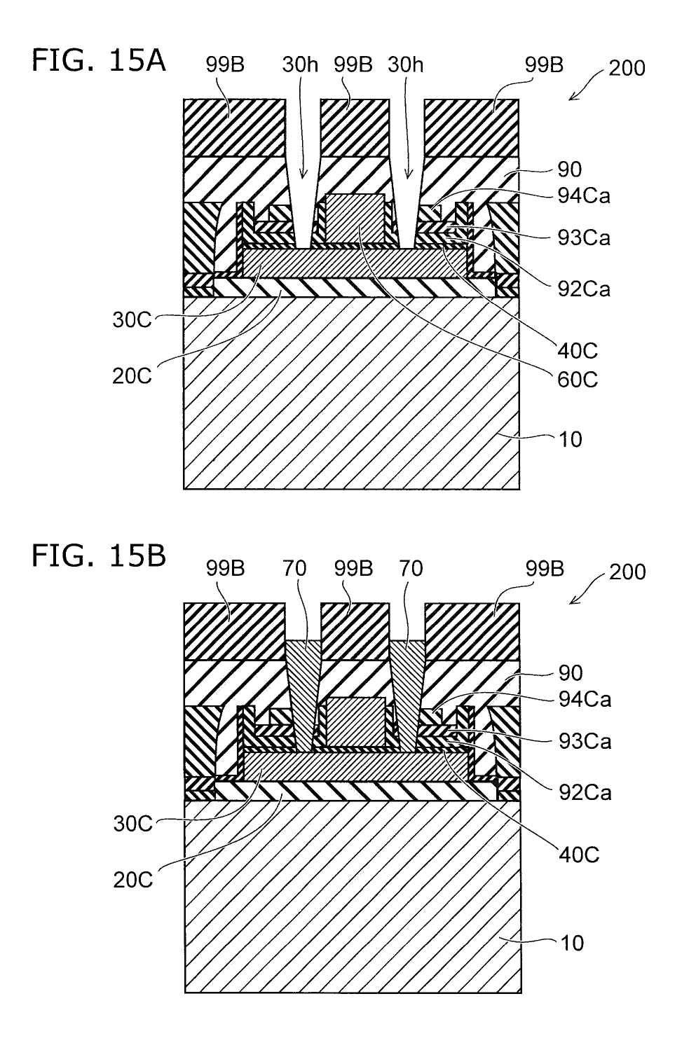

The cross section in the position along line D-D′ of FIG. 4B corresponds to FIGS. 15A and 15B. Next, as shown in FIG. 15A, in the peripheral region 200, a mask layer 99B is patterned on the interlayer insulating film 90. In the mask layer 99B, an opening with a circular planar shape, for example, is formed on both sides of the conductive layer 60C. Subsequently, RIE processing is performed to form a pair of contact holes 30h that pierce the interlayer insulating film 90, the insulating film 94Ca, the insulating film 93Ca, the insulating film 92Ca, and the insulating film 40C and reach the resistance element layer 30C.

Here, when a film containing silicon oxide is etched, etching is performed under conditions of a higher selection ratio than the conditions for etching a film containing silicon nitride.

Alternatively, conversely, when a film containing silicon nitride is etched, etching is performed under conditions of a higher selection ratio than the conditions for etching a film containing silicon oxide.

For example, when the interlayer insulating film 90 and the insulating film 94Ca containing silicon oxide are etched, etching is performed by switching the etching conditions of the interlayer insulating film 90 and the insulating film 94Ca to conditions where the etching rate is higher than the etching conditions of the insulating film 93Ca containing silicon nitride.

On the other hand, when the insulating film 93Ca containing silicon nitride is etched, etching is performed by switching the etching conditions of the insulating film 93Ca to conditions where the etching rate is higher than the etching conditions of the interlayer insulating film 90 and insulating film 94Ca containing silicon oxide.

After that, when the insulating film 92Ca and the insulating film 40C containing silicon oxide are etched, etching may be advanced by switching the etching conditions of the insulating film 92Ca and the insulating film 40C to conditions where the etching rate is higher than the etching conditions of the insulating film 93Ca.

When the contact hole 30h is formed, the insulating film 93Ca functions as a stopper film when the interlayer insulating film 90 and the insulating film 94Ca are processed by RIE. As described above, the resistance element layer 30C may be disposed in plural on the semiconductor layer 10. In such a case, the number of positions where the contact hole 30h is to be formed is plural.

By the existence of this stopper film, even if the etching rate of the insulating films 90 and 94Ca varies with positions, the contact hole 30h can be formed surely on the upper side of the stopper film in all the positions. By etching the stopper film (the insulating film 93Ca), the insulating film 92Ca, and the insulating film 40C, the contact hole 30h reaching the resistance element layer 30C can be formed surely.

Next, as shown in FIG. 15B, a conductive material is buried in the contact hole 30h. The contact 70 pierces the interlayer insulating film 90, the insulating film 94Ca, the insulating film 93Ca, the insulating film 92Ca, and the insulating film 40C and is connected to the resistance element layer 30C.

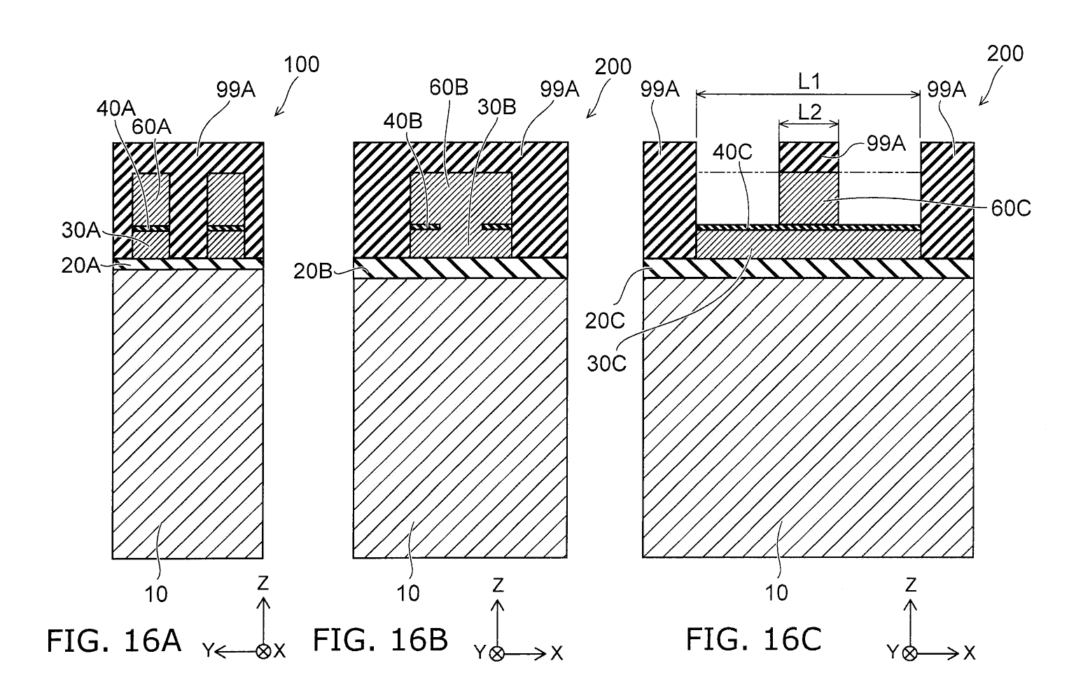

FIG. 16A to FIG. 23B are examples of schematic cross-sectional views showing the manufacturing process of a nonvolatile semiconductor memory device according to a reference example.

First, the same state as the state shown in FIG. 6A to FIG. 6C is prepared. The drawings of the numbers including “A” to “C” of FIG. 16A to FIG. 22C show the states after the state of FIG. 6A to FIG. 6C.

Next, the entire memory cell region 100 shown in FIG. 16A and the entire peripheral region 200 shown in FIGS. 16B and 16C are covered with the mask layer 99A. The mask layer 99A is formed by the spin coating method, for example. In the peripheral region 200 shown in FIG. 16C, the mask layer 99A is patterned. Subsequently, in the peripheral region 200 shown in FIG. 16C, RIE processing is performed on the conductive layer 60C. Thereby, portions of the conductive layer 60C provided on the resistance element layer 30C are removed. The length of the conductive layer 60C becomes a length of L2 shorter than the length L1, for example. After that, the mask layer 99A is removed.

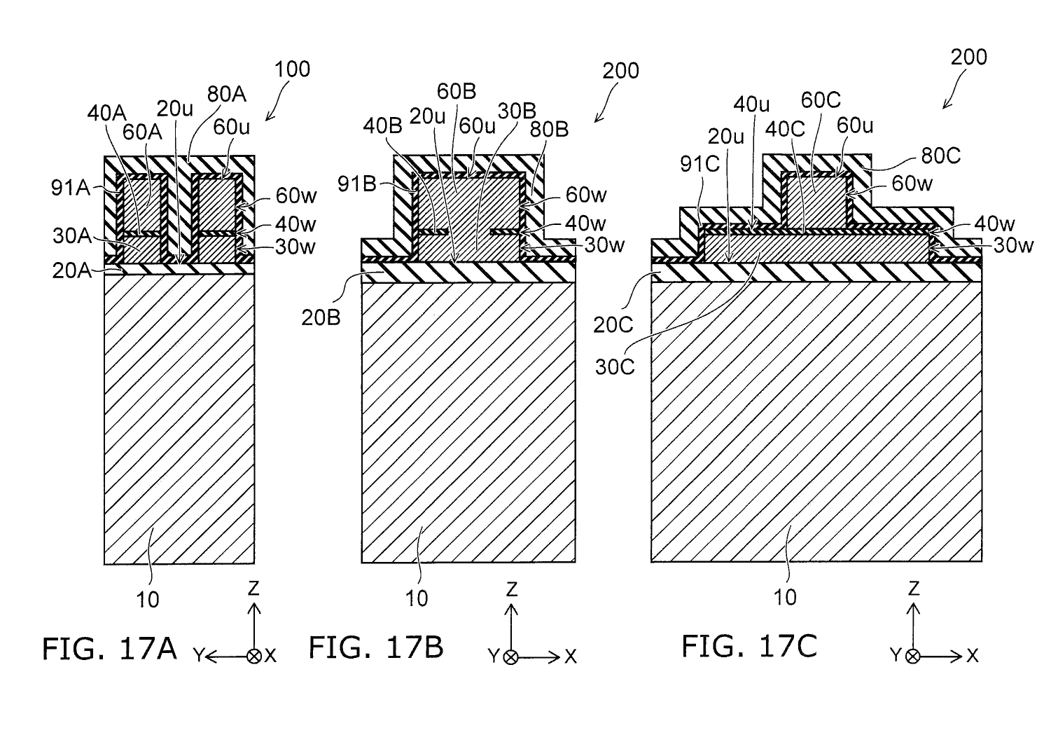

Next, in the memory cell region 100 shown in FIG. 17A, the insulating film 91A is formed conformally on the upper surface 20u of the gate insulating film 20A, the side surface 30w of the charge storage layer 30A, the side surface 40w of the gate insulating film 40A, and the side surface 60w and the upper surface 60u of the control gate electrode 60A.

In the peripheral region 200 shown in FIG. 17B, the insulating film 91B is formed conformally on the upper surface 20u of the gate insulating film 20B, the side surface 30w of the gate electrode 30B, the side surface 40w of the insulating film 40B, and the side surface 60w and the upper surface 60u of the gate electrode 60B.

In the peripheral region 200 shown in FIG. 17C, the insulating film 91C is formed conformally on the upper surface 20u of the insulating film 20C, the side surface 30w of the resistance element layer 30C, the side surface 40w and the upper surface 40u of the insulating film 40C, and the side surface 60w and the upper surface 60u of the conductive layer 60C.

Subsequently, in the memory cell region 100 shown in FIG. 17A, the sacrifice film 80A is formed on the insulating film 91A. In the memory cell region 100, the portion between memory cells is filled with the sacrifice film 80A. In the peripheral region 200 shown in FIG. 17B, the side wall film 80B is formed on the insulating film 91B. In the peripheral region 200 shown in FIG. 17B, the portion between adjacent gate electrodes 30B and the portion between adjacent gate electrodes 60B are not filled up with the side wall film 80B. The side wall film 80B is formed so as to be a thin layer lying along the upper surface of the gate insulating film 20B, the side surfaces of the gate electrodes 30B and 60B, and the upper surface of the gate electrode 60B via the insulating film 91B. In the peripheral region 200 shown in FIG. 17C, the side wall film 80C is formed on the insulating film 91C. The side wall film 80C is formed so as to be a thin layer lying along the upper surface of the insulating film 20C, the side surface and part of the upper surface of the resistance element layer 30c, and the side surface and the upper surface of the conductive layer 60C via the insulating film 91C.

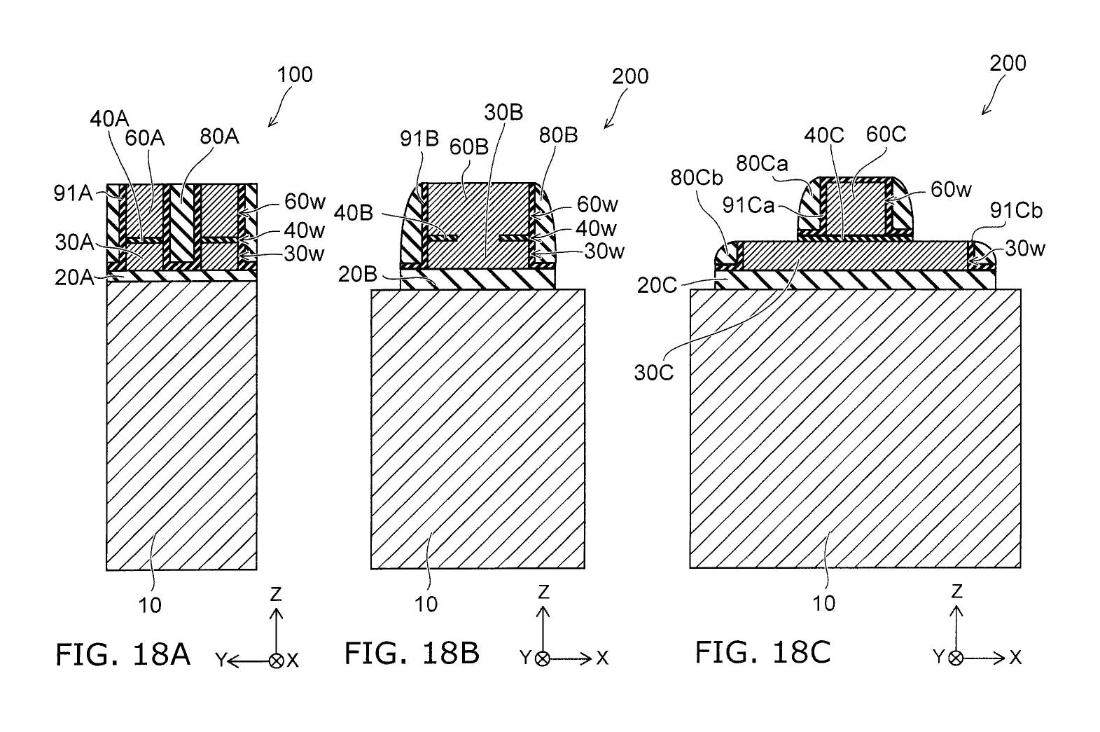

Next, dry etching processing (for example, anisotropic etching processing) is performed on the memory cell region 100 shown in FIG. 18A and the peripheral region 200 shown in FIGS. 18B and 18C, for example.

Thereby, in the memory cell region 100 shown in FIG. 18A, the insulating film 91A and the sacrifice film 80A on the upper side of the control gate electrode 60A are removed. Consequently, the sacrifice film 80A is formed between control gate electrodes 60A and between charge storage layers 30A. The sacrifice film 80A extends in the X-direction.

In the peripheral region 200 shown in FIG. 18B, the side wall film 80B is formed on the side surface 30w of the gate electrode 30B, the side surface 40w of the insulating film 40B, and the side surface 60w of the gate electrode 60B via the insulating film 91B.

In the peripheral region 200 shown in FIG. 18C, a side wall film 80Ca is formed on the side surface 60w of the conductive layer 60C via an insulating film 91Ca. Furthermore, a side wall film 80Cb is formed on the side surface 30w of the resistance element layer 30C via an insulating film 91Cb.

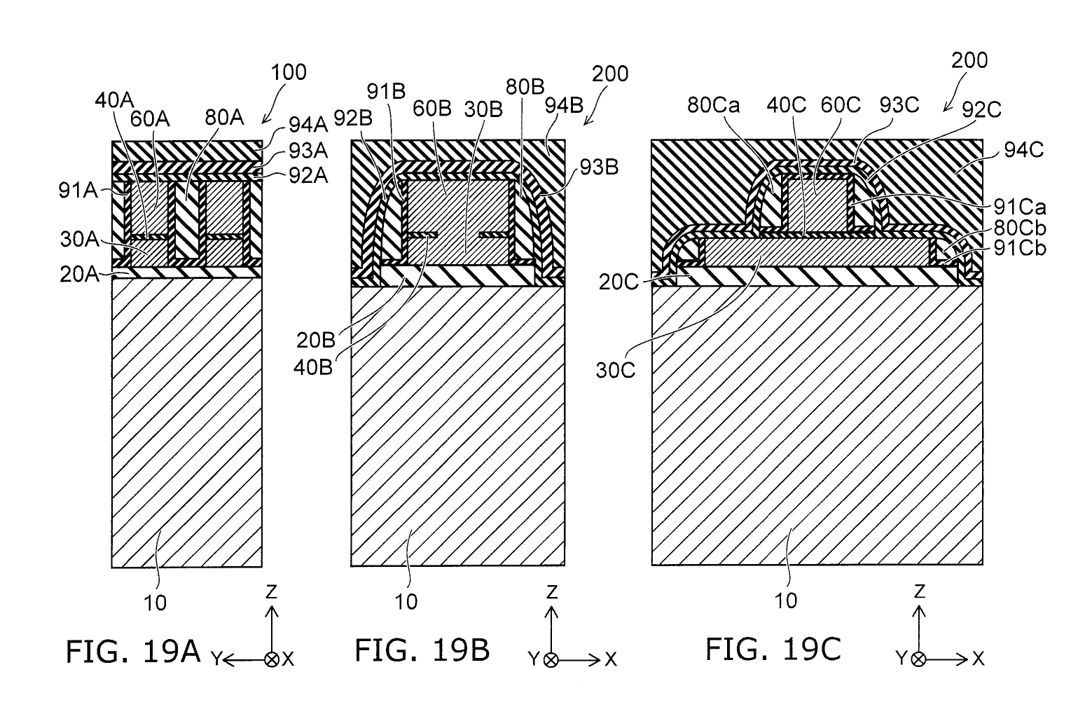

Next, in the memory cell region 100 shown in FIG. 19A, the insulating film 92A is formed on the control gate electrode 60A, on the sacrifice film 80A, and on the insulating film 91A. The insulating film 93A is formed on the insulating film 92A. The insulating film 94A is formed on the insulating film 93A.

In the peripheral region 200 shown in FIG. 19B, the insulating film 92B is formed on the semiconductor layer 10, on the insulating film 91B, on the side wall film 80B, and on the gate electrode 60B. The insulating film 93B is formed on the insulating film 92B. The insulating film 94B is formed on the insulating film 93B.

In the peripheral region 200 shown in FIG. 19C, the insulating film 92C is formed on the semiconductor layer 10, on the insulating film 91Cb, on the side wall film 80Cb, on the resistance element layer 30C, on the insulating film 40C, on the insulating film 91Ca, and on the side wall film 80Ca. The insulating film 93C is formed on the insulating film 92C. The insulating film 94C is formed on the insulating film 93C.

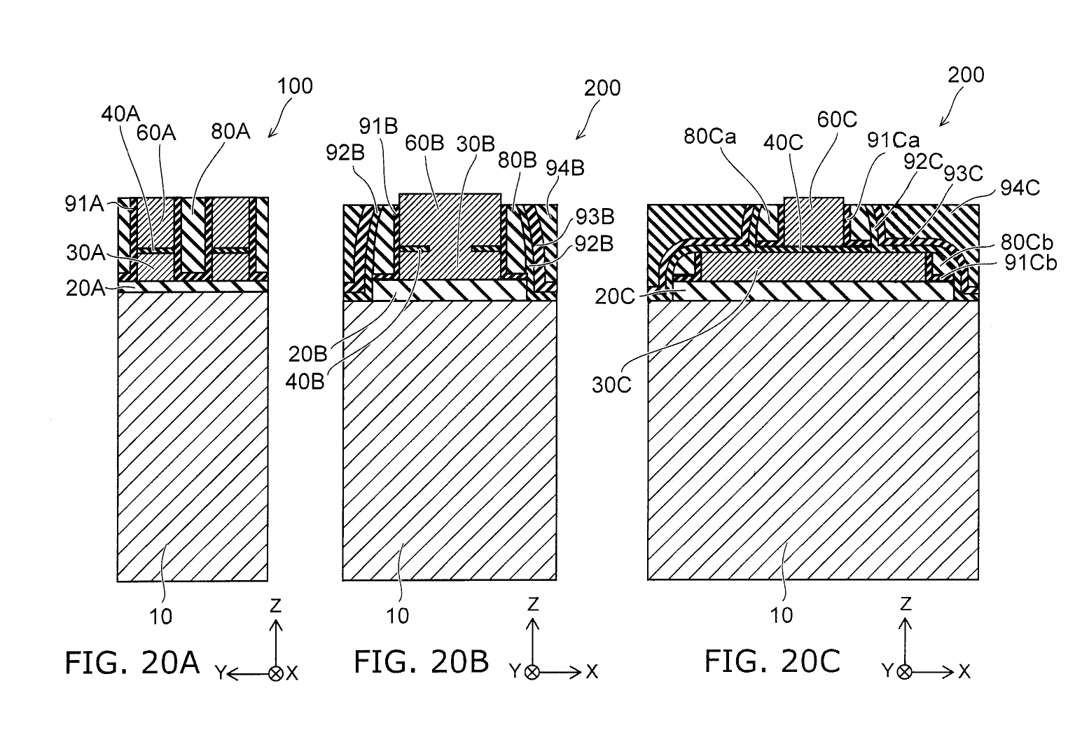

Next, the insulating films 93A, 93B, and 93C are used as a stopper film to perform CMP processing on the insulating films 94A, 94B, and 94C. Subsequently, dry etching processing (for example, RIE processing) is performed on the insulating films 92A, 92B, and 92C and the insulating films 93A, 93B, and 93C until the control gate electrode 60A, the gate electrode 60B, and the conductive layer 60C are exposed. FIG. 20A to FIG. 20C show this state.

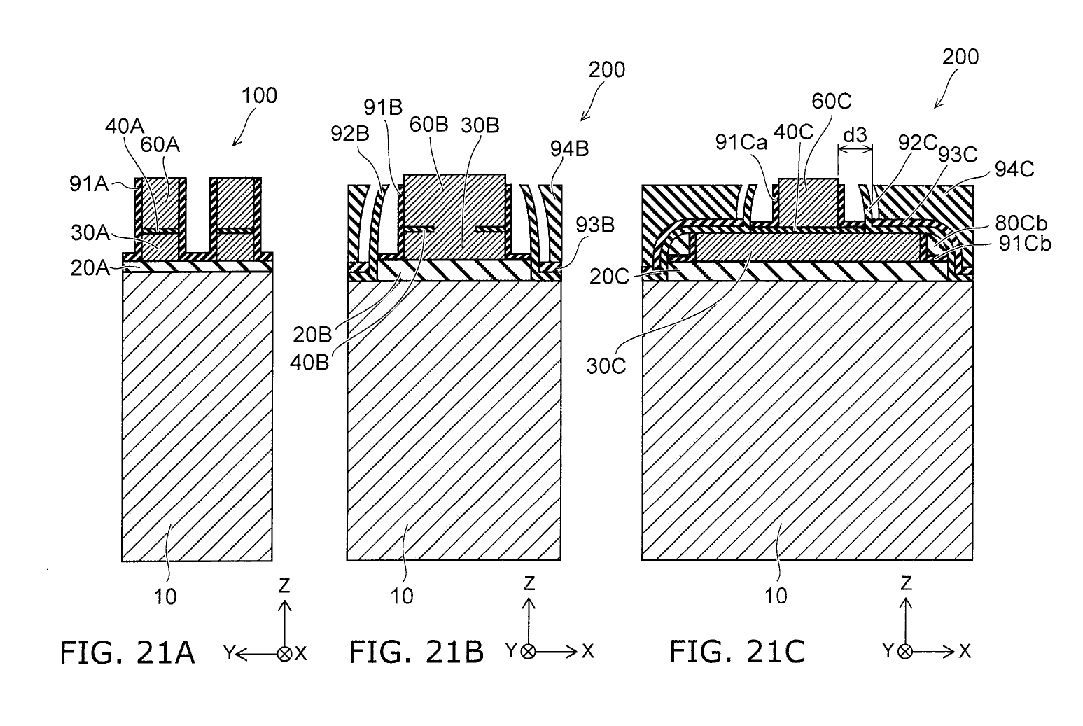

Next, as shown in FIG. 21A to FIG. 21C, wet etching processing is performed on the sacrifice film 80A, the side wall films 80B and 80Ca, and the insulating films 93B and 93C. A phosphoric acid solution may be used for the wet etching processing, for example.

Thereby, in the memory cell region 100 shown in FIG. 21A, the sacrifice film 80A is removed from between control gate electrodes 60A. In other words, the sacrifice film 80A is removed from between memory cells. In the peripheral region 200 shown in FIG. 21B, the side wall film 80B is removed. Furthermore, part of the insulating film 93B is removed, and the insulating film 93B remains on the insulating film 92B. In the peripheral region 200 shown in FIG. 21C, the side wall film 80Ca is removed. Furthermore, part of the insulating film 93C is removed, and the insulating film 93C remains on the insulating film 92C.

At this stage, in the peripheral region 200 shown in FIG. 21C, the insulating film 93C is formed on portions of the resistance element layer 30C where the conductive layer 60C is not provided, at a distance of d3 from the conductive layer 60C. Here, the distance d3 is longer than the distance d1. This is because, as shown in FIG. 20C, the distance d1 is almost equal to the film thickness of the insulating film 92, whereas the distance d3 is almost equal to the total film thickness of the insulating film 91Ca, the sacrifice film 80Ca, and the insulating film 92C (equivalent to the insulating film 92Ca).

Next, the interlayer insulating film 90 is formed in the memory cell region 100 and the peripheral region 200.

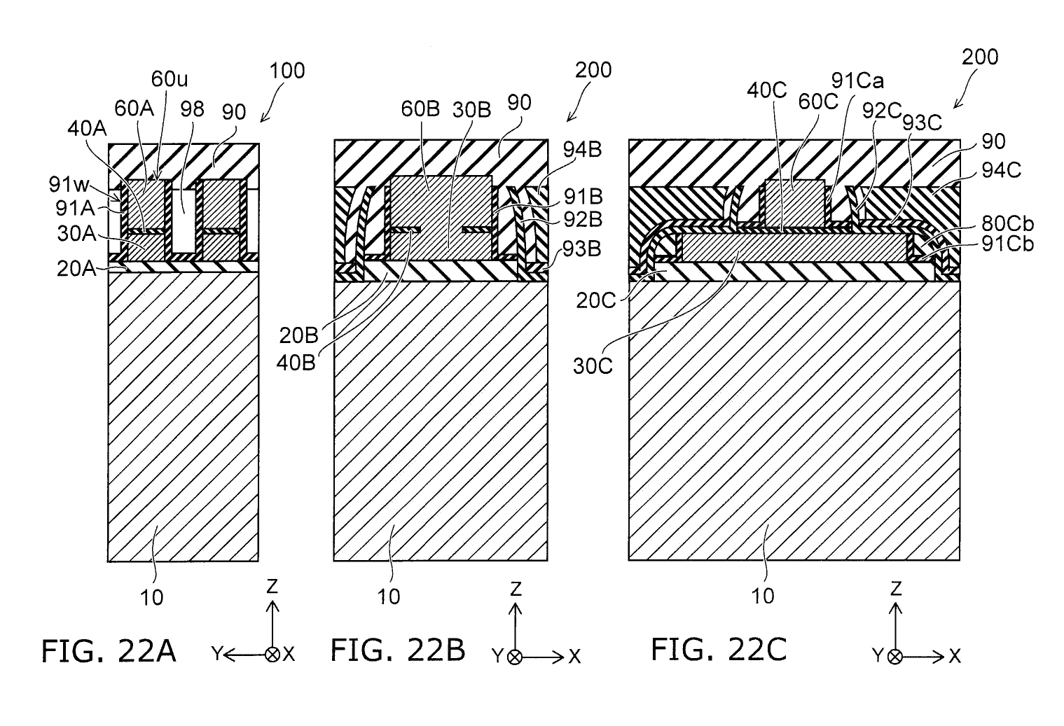

For example, in the memory cell region 100 shown in FIG. 22A, the interlayer insulating film 90 is formed such that a space 98 remains between memory cells. The interlayer insulating film 90 covers the upper surface 60u of the control gate electrode 60A and an upper portion of the side surface 91w of the insulating film 91A.

In the peripheral region 200 shown in FIG. 22B, the interlayer insulating film 90 is formed on the gate electrode 60B, on each of the insulating films 91B, 92B, and 94B, between the insulating film 91B and the insulating film 92B, and between the insulating film 92B and the insulating film 94B.

In the peripheral region 200 shown in FIG. 22C, the interlayer insulating film 90 is formed on the conductive layer 60C, on each of the insulating films 91Ca, 92C, 93C, and 94C, between the insulating film 91Ca and the insulating film 92C, and between the insulating film 92C and the insulating film 94C.

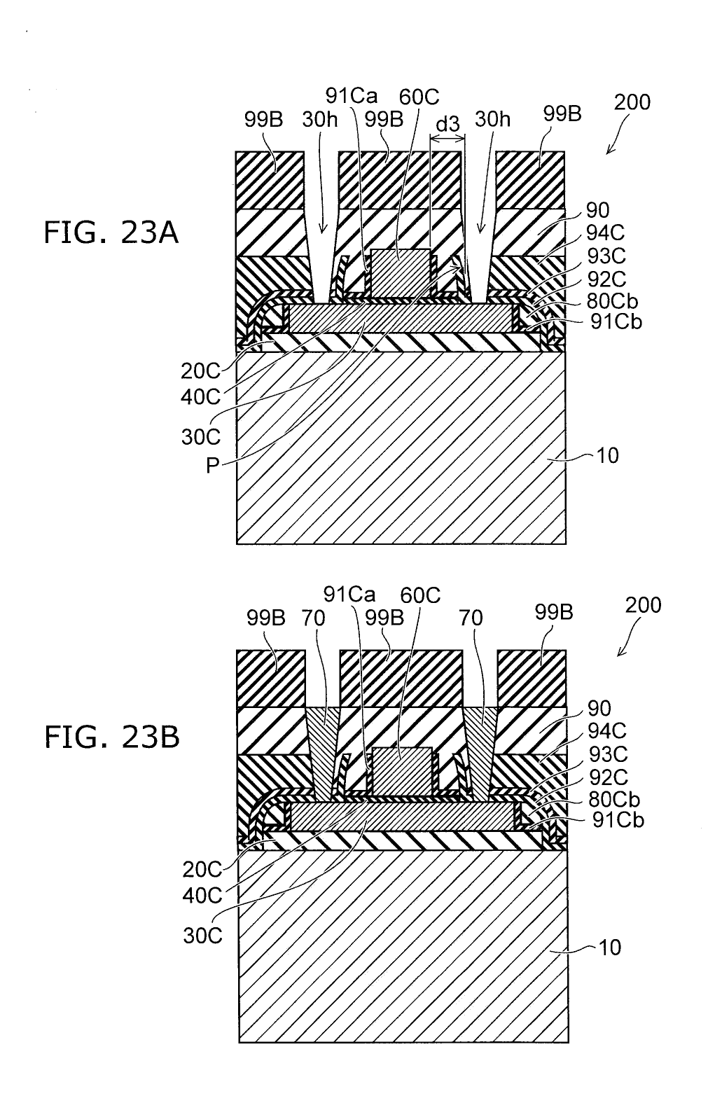

Next, the state after FIG. 22C is described. As shown in FIG. 23A, in the peripheral region 200, the mask layer 99B is patterned on the interlayer insulating film 90. Subsequently, RIE processing is performed to form a pair of contact holes 30h that pierces the interlayer insulating film 90, the insulating film 94C, the insulating film 93C, and the insulating film 92C and reach the resistance element layer 30C. Here, the insulating film 93C functions as a stopper film in the RIE processing. Next, as shown in FIG. 23B, the contact 70 is formed in the contact hole 30h. The contact 70 is connected to the resistance element layer 30C.

Also in the manufacturing process according to the reference example, the contact hole 30h for forming the contact 70 is formed. However, in the manufacturing process according to the reference example, part of the insulating film 92C (the portion indicated by arrow p of FIG. 23A) remains near the conductive layer 60C.

To form a contact hole 30h with a good shape, the contact hole 30h is preferably formed in a position away from the portion indicated by arrow p of FIG. 23A. Alternatively, in the case of using a stopper film (the insulating film 93C), the contact hole 30h needs to be formed in a position at a distance of d3 (d3>d1) from the conductive layer 60C. This is because the stopper film (the insulating film 93C) is provided in a position at a distance of d3 from the conductive layer 60C. Thus, in the manufacturing process according to the reference example, the distance between the contact 70 and the conductive layer 60C cannot be shortened.

Furthermore, in the manufacturing process according to the reference example, when RIE processing is performed on the conductive layer 60C, the memory cell region 100 is covered with the mask layer 99A (FIG. 16A). In this case, the plurality of memory cells provided apart from one another support the mask layer 99A. If a cleaning process or the like is performed after the mask layer 99A is removed, the cleaning liquid may get between memory cells. Consequently, in the reference example, memory cells are likely to collapse during the manufacturing process.

In contrast, in the manufacturing process according to the first embodiment, the insulating film 93C functioning as a stopper film can be brought close up to the distance d1 (d1<d3) from the conductive layer 60C.

Hence, in the manufacturing process according to the first embodiment, the contact 70 can be brought closer to the conductive layer 60C. Thereby, the distance between the contact 70 and the conductive layer 60C can be made shorter. Consequently, the flexibility of the arrangement of contacts 70 is increased.

Furthermore, when RIE processing is performed on the conductive layer 60C as shown in FIG. 10C, although the memory cell region 100 is covered with the mask layer 99A, the sacrifice film 80A is provided between memory cells as shown in FIG. 10A. Thereby, the side surfaces of the plurality of memory cells are supported by the sacrifice film 80A when the mask layer 99A is formed or when cleaning treatment is performed after the removal of the mask layer 99A. Consequently, in the first embodiment, probability of collapsing of memory cell during the manufacturing process can be less, and the manufacturing yield is increased. Furthermore, since probability of collapsing of memory cell is less, the reliability of the nonvolatile semiconductor memory device is improved.

### Second Embodiment

A second embodiment in which the memory cell region or the resistance element layer is formed and a shape of the memory cell will now be described.

Before describing the second embodiment, what is called double patterning processing and loop cut technique are described.

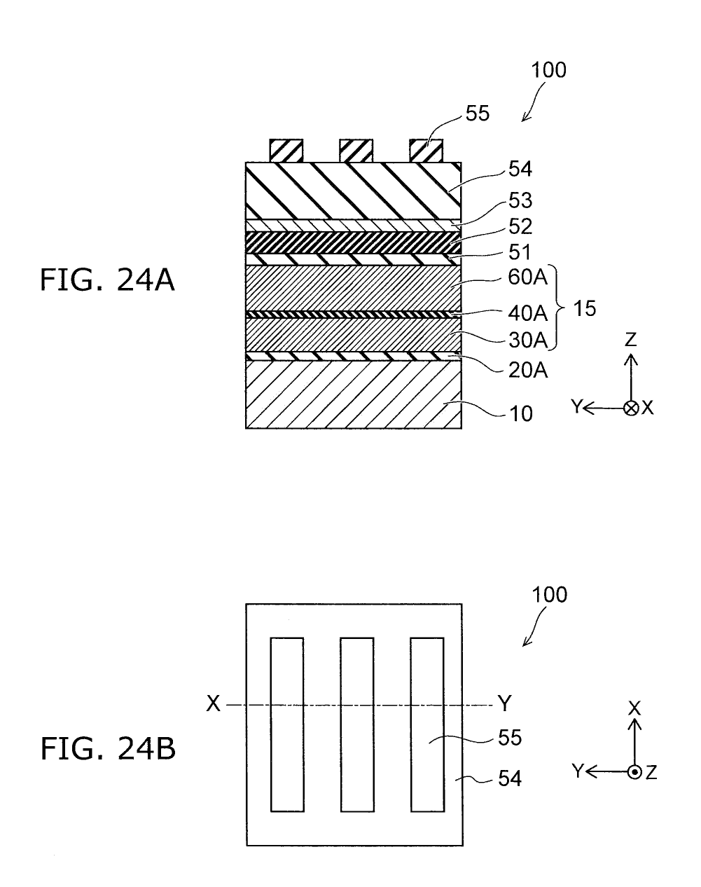

FIG. 24A to FIG. 34 are examples of schematic views describing the double patterning process and the loop cut process.

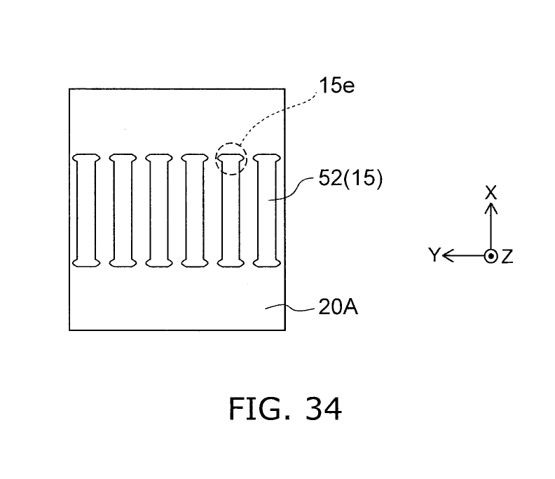

Here, the drawings of the numbers including “A” of FIG. 24A to FIG. 33B show schematic cross-sectional views showing the double patterning process and the loop cut process, and the drawings of the numbers including “B” show schematic plan views showing the double patterning process and the loop cut process. The drawings of the numbers including “A” show the X-Y cross section of the drawings of the numbers including “B”. FIG. 34 shows a schematic plan view describing the double patterning process and the loop cut process.

As shown in FIG. 24A and FIG. 24B, the gate insulating film 20A is formed above the semiconductor layer 10. Further, a stacked body 15 in which the charge storage layer 30A, the gate insulating film 40A, and the control gate electrode 60A are stacked is formed above the gate insulating film 20A.

FIG. 24A shows a state where the memory cell region 100 is cut along the YZ plane. An insulating film 51, an insulating film 52, a semiconductor film 53, and an insulating film 54 are further stacked on the stacked body 15. The material of the insulating film 51 contains silicon nitride, for example. The material of the insulating films 52 and 54 is silicon oxide, for example. The material of the semiconductor film 53 is silicon, for example. Resists 55 extending in the X-direction are provided above the insulating film 54. The resists 55 extending in the X-direction are aligned in the Y-direction.

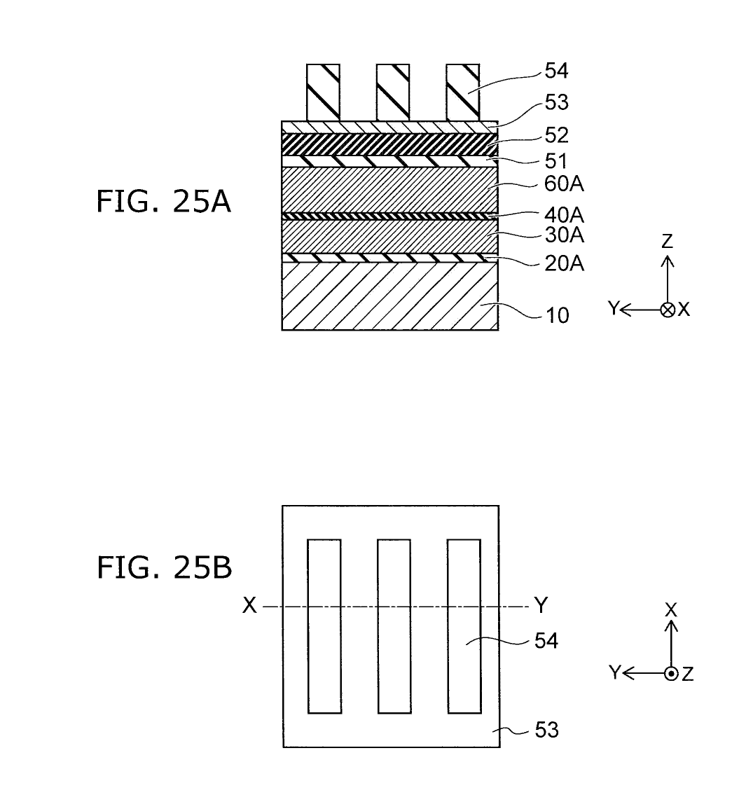

Next, as shown in FIG. 25A and FIG. 25B, the resists 55 are used as a mask to perform RIE processing on the insulating film 54. Thereby, insulating films 54 extending in the X-direction are formed above the semiconductor film 53.

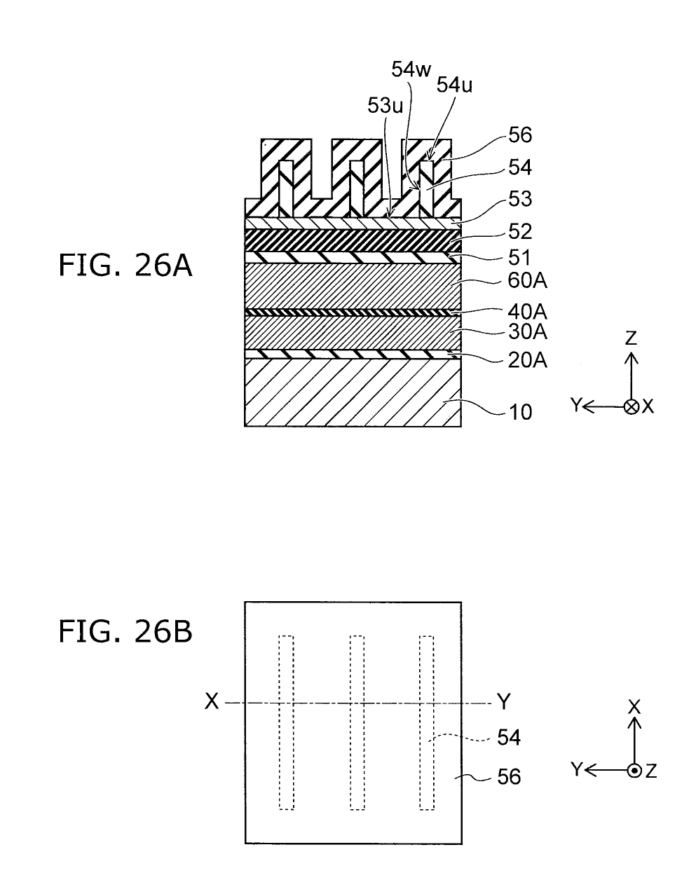

Next, the width in the Y-direction of the insulating film 54 is shortened to approximately ⅓ of the spacing in the Y-direction between insulating films 54 (slimming processing). Subsequently, as shown in FIG. 26A and FIG. 26B, a spacer film 56 is formed on the upper surface 53u of the semiconductor film 53, on the side surface 54w of the insulating film 54, and on the upper surface 54u of the insulating film 54. The material of the spacer film 56 is silicon nitride, for example.

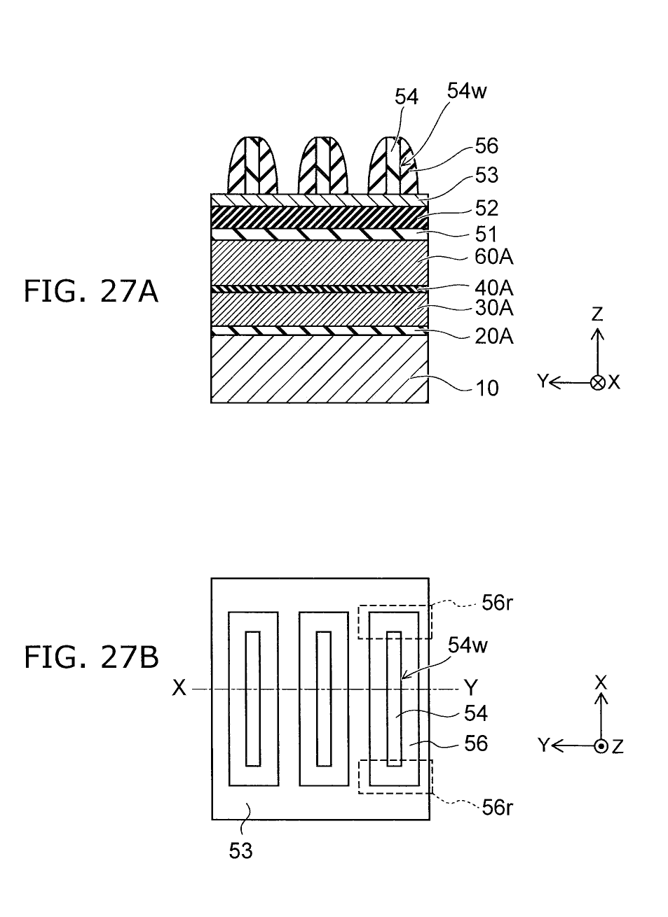

Next, as shown in FIG. 27A and FIG. 27B, dry etching processing (for example, anisotropic etching processing) is performed on the spacer film 56, for example. Thereby, the spacer film 56 is formed on the side surface 54w of the insulating film 54. As shown in FIG. 27B, the insulating film 54 is surrounded by the spacer film 56. Since the spacer film 56 surrounds the outer periphery of the insulating film 54 as viewed in the Z-direction, in the spacer film 56 there is a turning portion 56r connecting the end portions of two sets of spacer films 56 extending in the X-direction (hereinbelow, the turning portion is referred to as a loop portion).

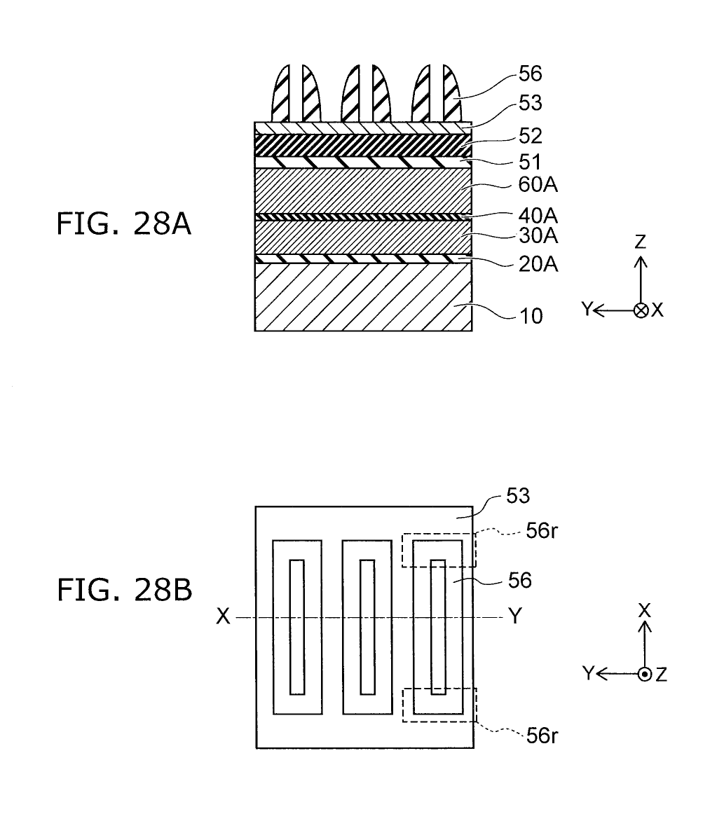

Next, as shown in FIG. 28A and FIG. 28B, the insulating film 54 is selectively removed. Thereby, the spacer film 56 remains on the semiconductor film 53. In the spacer film 56, the pitch in the Y-direction of the spacer film 56 other than the loop portion 56r is approximately half the pitch of the insulating film 54. The technique, which the spacer film 56 with a pitch half the pitch of the insulating film 54 is formed and is processing using the spacer film 56, is called the double patterning process.

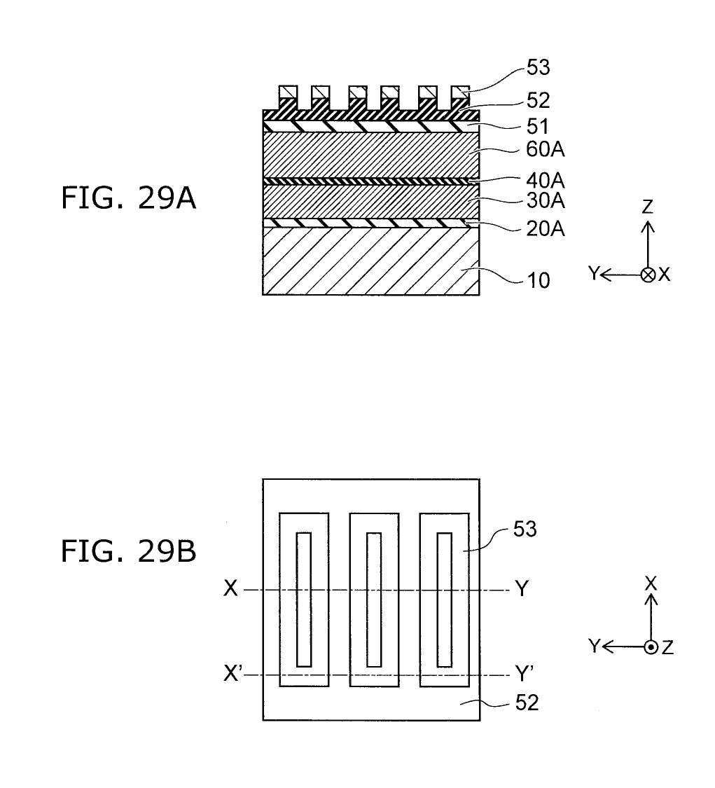

Subsequently, the spacer film 56 is used as a mask to perform RIE processing on the semiconductor film 53 and the insulating film 52 disposed under the spacer film 56. After the RIE processing, the spacer film 56 is removed. FIG. 29A and FIG. 29B show this state.

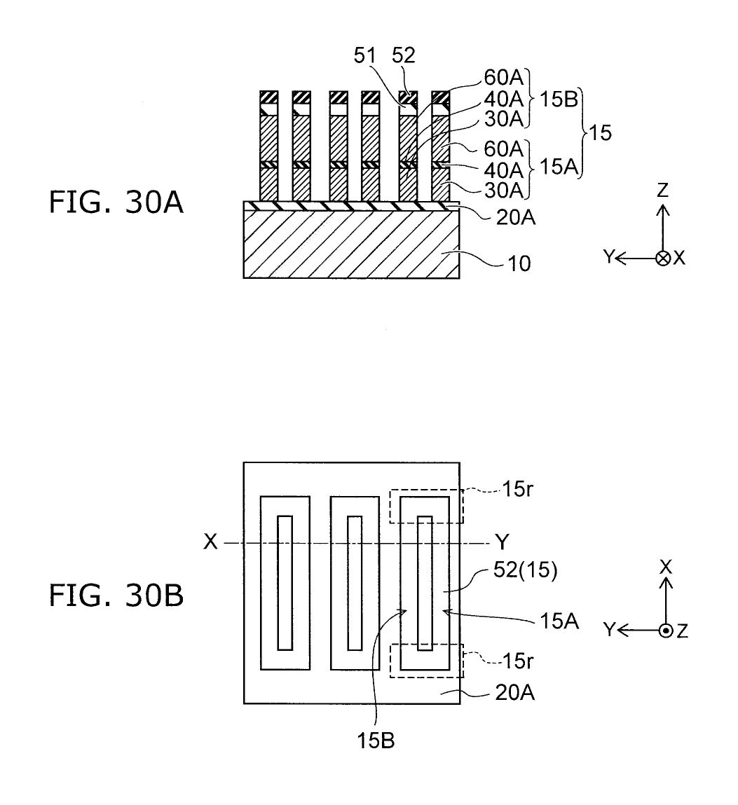

Then, the semiconductor film 53 is used as a mask to perform RIE processing on the insulating film 52, the insulating film 51, and the stacked body 15. After the RIE processing, the semiconductor film 53 is removed. FIG. 30A and FIG. 30B show this state.

Also in the stacked body 15 after the RIE processing, the pattern configuration of the loop portion 56r of the spacer film 56 is left. Thus, the stacked body 15 has a loop portion 15r. When the nonvolatile semiconductor memory device is finally formed while the loop portion 15r is left, adjacent stacked bodies 15A and 15B are connected together via the loop portion 15r. Hence, the control gate electrode 60A of the stacked body 15A and the control gate electrode 60A of the stacked body 15B are electrically connectedeach other. Consequently, it is a possibile not to perform the writing, reading, and erasing of data to memory cell. Thus, in the case where the double patterning process is employed, the loop portion 15r may be cut (removed).

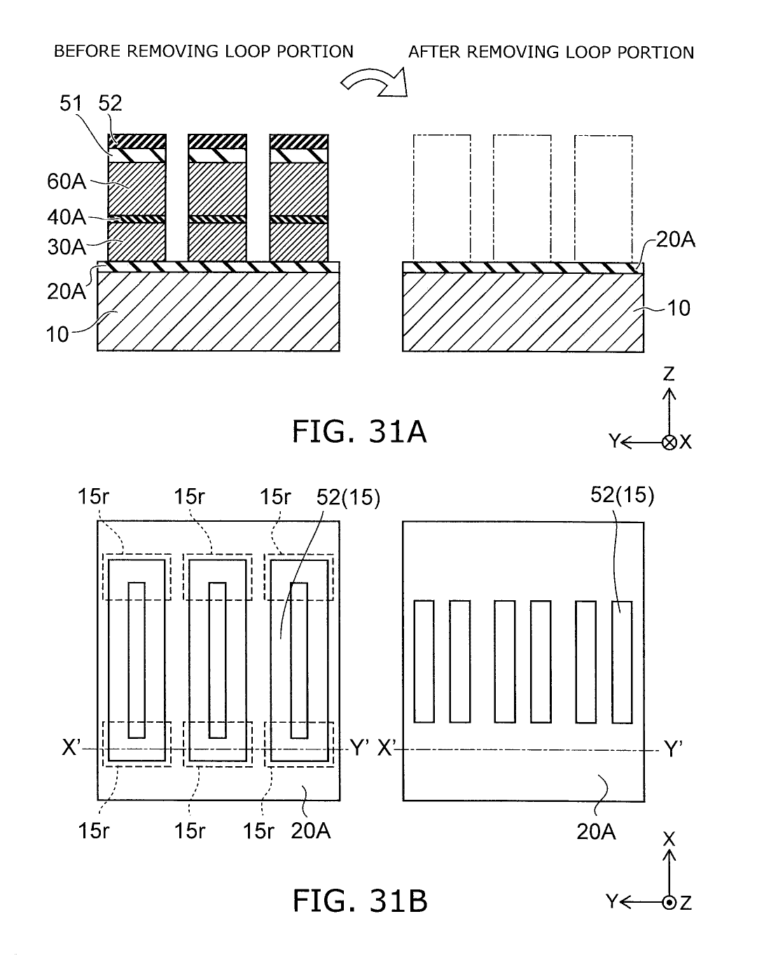

As a first method for cutting the loop portion 15r, there is a method in which, as shown in FIG. 30B, a loop form, which the stacked body 15 is not discontinuous in any position, is obtained and the loop portions 15r located in end portions in the X-direction are removed afterward, for example. As shown in FIG. 31A and FIG. 31B, the loop portion 15r is selectively removed by RIE processing, for example. Here, FIG. 31A shows a cross section in the position along line X′-Y′ of FIG. 31B. Thereby, stacked bodies 15 arranged in the Y-direction and each extending in the X-direction independently are formed.

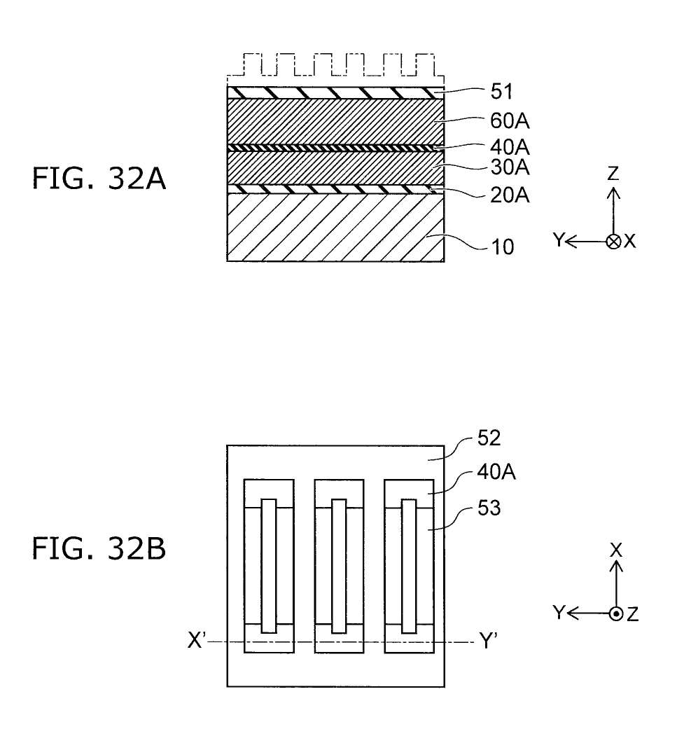

Alternatively, as a second method, there is a method in which the loop portion 15r is selectively removed by RIE processing from the state shown in FIG. 29A and FIG. 29B. FIG. 32A and FIG. 32B show this method. Here, FIG. 32A shows a cross section in the position along line X′-Y′ of FIG. 32B. FIG. 32A shows a state where the insulating film 52 and the semiconductor film 53 in the loop portion are removed from the state of FIG. 29A, for example.

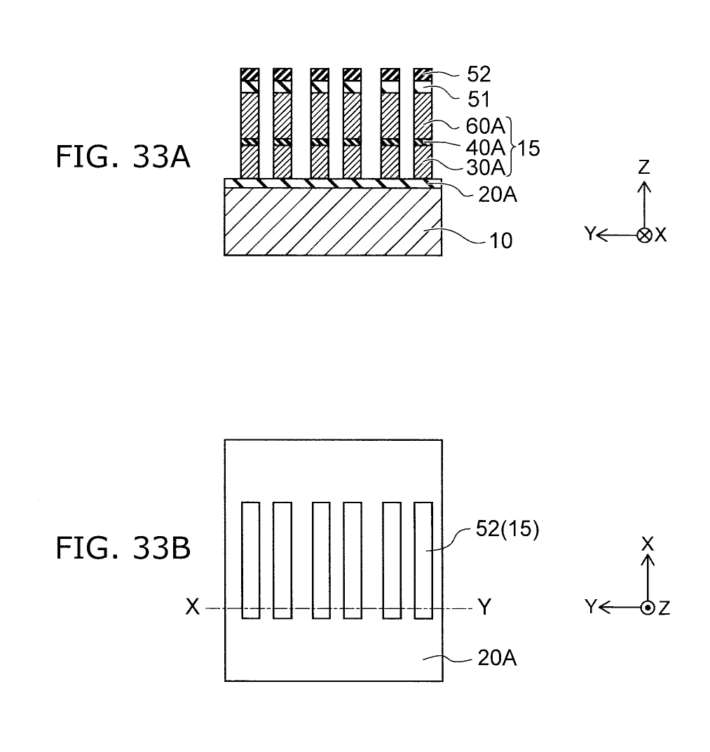

In the second method, after that, RIE processing (the second RIE processing) is further performed on portions other than the loop portion 15r to form stacked bodies 15 arranged in the Y-direction and extending in the X-direction independently, as shown in FIG. 33A and FIG. 33B.

However, in the first method, before the loop portion 15r is removed, the stacked bodies 15 with a high aspect ratio have already been arranged in the Y-direction in the X-Y cross section shown in FIG. 30A. Therefore, there may be a possibility that memory cells (stacked bodies 15) will collapse during the process of removing the loop portion 15r, for example.

In the second method, as shown in FIG. 34, a residue produced during the second RIE processing may re-adhere to an end portion 15e of the stacked body 15. Therefore, the width of the end portion 15e of the stacked body 15 may be expanded. As a result, the distance between adjacent stacked bodies 15 may become smaller, and the dielectric breakdown voltage between the control gate electrodes of memory cells may be reduced.

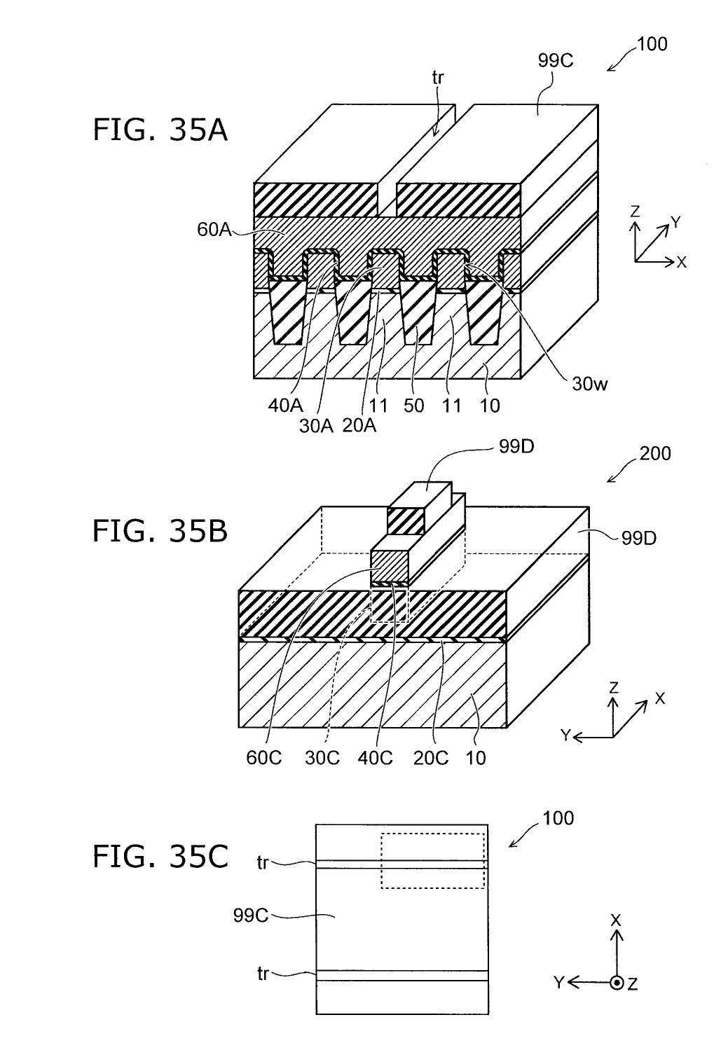

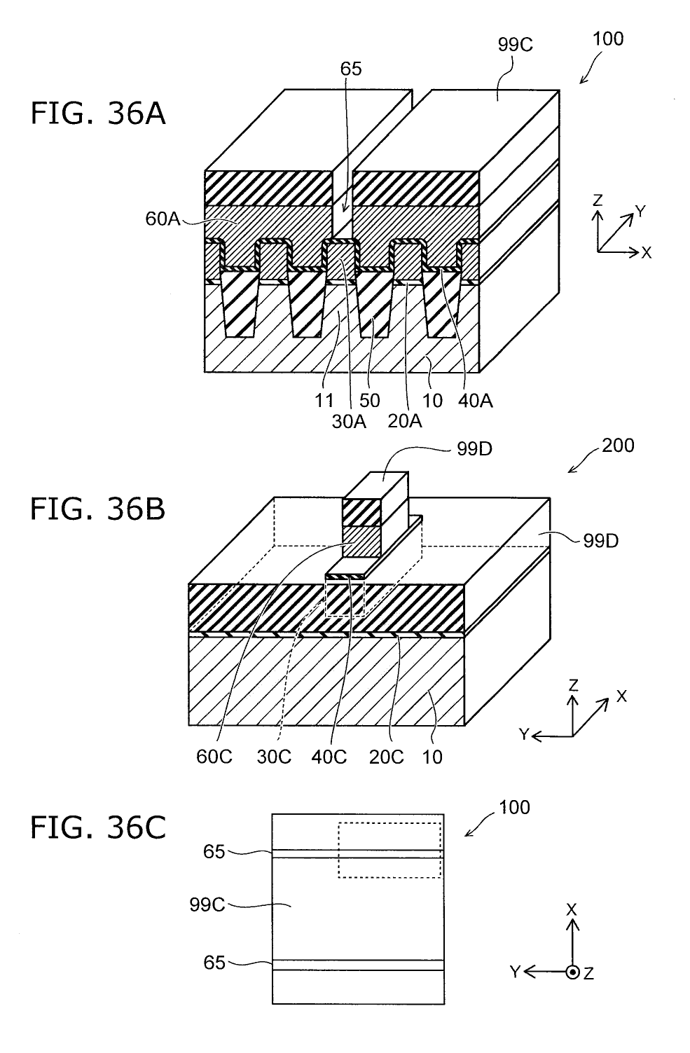

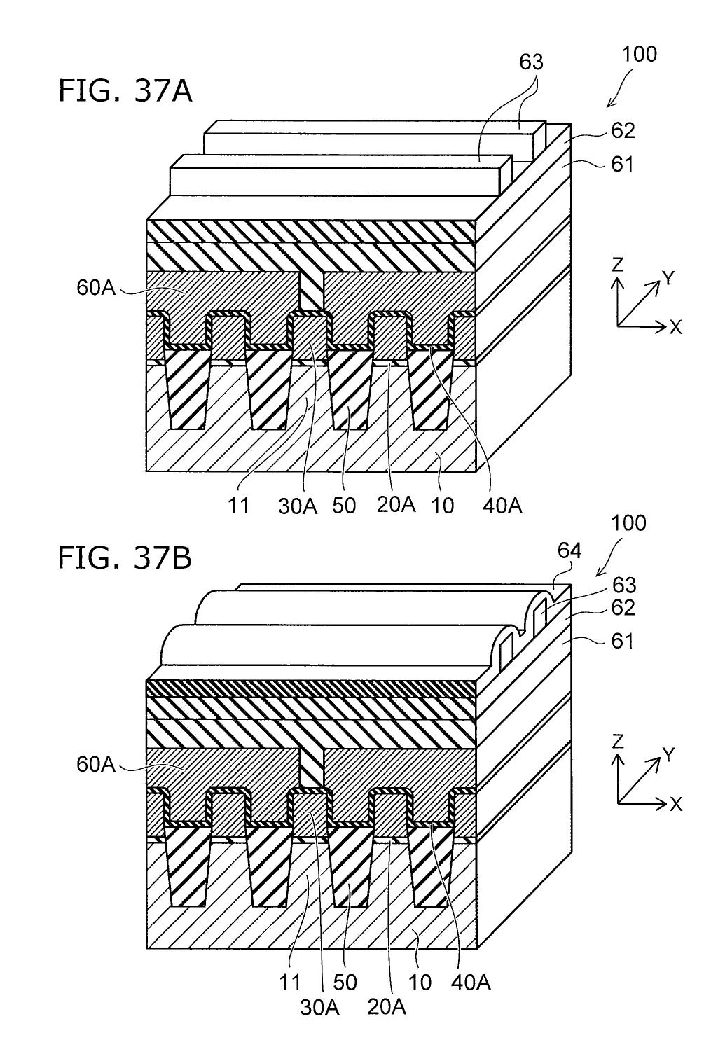

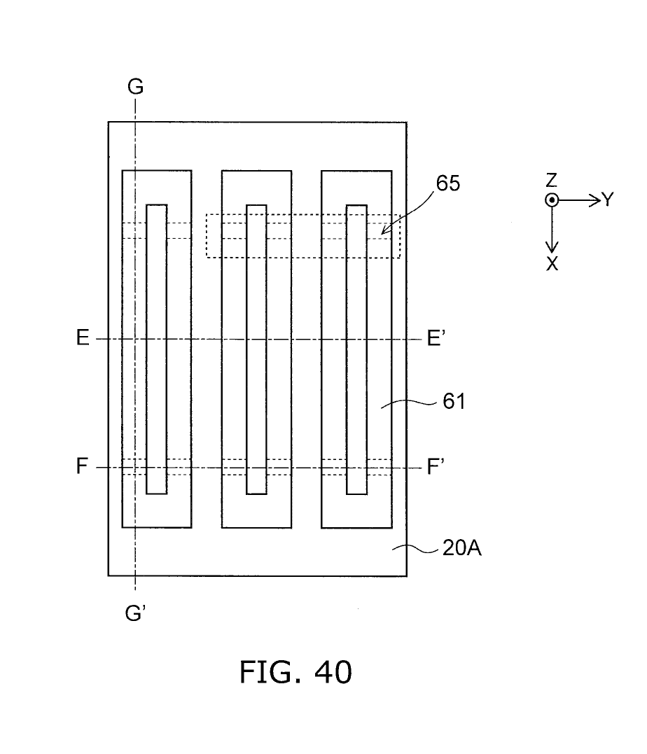

FIG. 35A to FIG. 39B are examples of schematic views showing the manufacturing process of a nonvolatile semiconductor memory device according to the second embodiment. FIG. 35A and FIG. 36A are views of the dotted line portion of the drawings of the numbers including “C”, and FIG. 37A to FIG. 39B are views of the dotted line portion of FIG. 40.

In FIG. 35A, FIG. 36A, and FIG. 37A to FIG. 39B, the X-Z plane composed of the X-direction in which element isolation regions 50 are aligned in the memory cell region 100 and the Z-direction is shown on this side. In FIG. 35B and FIG. 36B, the Y-Z plane perpendicular to the X-direction in which the conductive layer 60c extends is shown on this side. The XYZ-axes of FIG. 35A to FIG. 39B agree with the XYZ-axes of FIGS. 25A to 34.

First, in the memory cell region 100 shown in FIG. 35A, the semiconductor layer 10, element regions 11, the gate insulating film 20A, the charge storage layer 30A, and the gate insulating film 40A are formed. Further, the control gate electrode layer 60A is formed on the gate insulating film 40A.

The element regions 11 are formed by separating the semiconductor layer 10 in the X-direction and element regions extend the semiconductor layer 10 in the Y-direction crossing the X-direction. The gate insulating film 20A is provided on the element regions 11. The charge storage layers 30A are provided above the gate insulating film 20A, and extend in the Y-direction. The gate insulating film 40A is provided on the charge storage layers 30A and on at least part of the side surface 30w of the charge storage layers 30A.

Subsequently, a mask layer 99C is disposed above the control gate electrode layer 60A and the mask layer 99C is patternd. For example, the mask layer 99C is patterned on the control gate electrode layer 60A so that a trench tr extending in the Y-direction is formed. The mask layer 99C is a resist or the like, for example. Here, the trench tr is formed near the end in the Y-direction of the position where the stacked body 15 extending in the X-direction is to be formed.

In the peripheral region 200 shown in FIG. 35B, simultaneously with the formation of the charge storage layer 30A, the resistance element layer 30C is formed above the semiconductor layer 10 via the insulating film 20C. Further, simultaneously with processing of the control gate electrode layer 60A, the conductive layer 60C is formed on the resistance element layer 30C via the insulating film 40C.

Subsequently, a mask layer 99D exposing part of the conductive layer 60C is formed on the conductive layer 60C. The mask layer 99D is further formed on the insulating film 20C. The mask layer 99D is a resist or the like, for example.

Next, in the memory cell region 100 shown in FIG. 36A, a cut portion 65 is formed in the control gate electrode layer 60A. The cut portion 65 separates the control gate electrode layer 60A in the X-direction. For example, RIE processing is performed on the control gate electrode layer 60A opened from the mask layer 99C to separate the control gate electrode layer 60A in the X-direction. After that, the mask layer 99A is removed. Here, the cut portion 65 may be formed above the charge storage layer 30A; thereby, the film thickness of the control gate electrode layer 60A removed can be reduced and the processing can be made easier. The cut portion 65 needs only to divide the control gate electrode layer 60A, and may be formed on the element isolation region 50 or formed so as to extend over the charge storage layer 30A and the element isolation region 50.

In the peripheral region 200 shown in FIG. 36B, simultaneously with the separation of the control gate electrode layer 60A in the X-direction, a part of the conductive layer 60C provided on the resistance element layer 30C are removed as using the mask layer 99D. Then, the mask layer 99D is removed. After that, the control gate electrode layer 60A is divided in the Y-direction by double patterning technique. This is a process corresponding to FIGS. 10A to 10C of the first embodiment.

In the resistance element layer 30C, the structure of FIGS. 3A and 3B can be formed through the subsequent processes of FIGS. 12A to 15B.

Next, as shown in FIG. 37A, in the memory cell region 100, an insulating film 61 is formed in the trench tr and on the control gate electrode layer 60A. The insulating film 61 is silicon nitride, for example. The insulating film 61 may be used as a protection insulating film that protects the control gate electrode layer 60A. That is, by forming the insulating film 61 also in the trench between control gate electrode layers 60A, the oxidation etc. of the control gate electrode layer 60A can be prevented. Subsequently, an insulating film 62 is formed above the insulating film 61. The insulating film 62 contains amorphous silicon, for example. Further, insulating films 63 extending in the X-direction are formed above the insulating film 62. The insulating film 63 contains silicon nitride, for example. Subsequently, a spacer film 64 is formed on the insulating film 62 and on the insulating film 63. The spacer film 64 contains silicon oxide, for example.

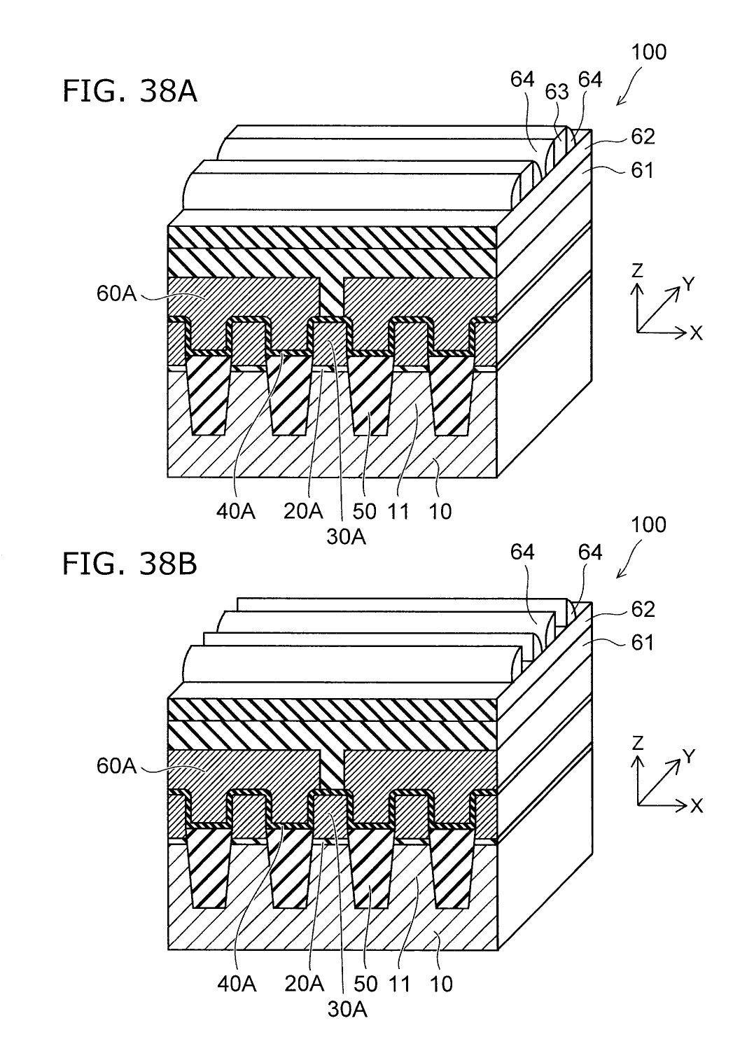

Next, dry etching processing (for example, anisotropic etching processing) is performed on the spacer film 64, for example. In the dry etching processing, the spacer film 64 remains on the side surface of the insulating film 63 due to the shielding effect of the insulating film 63. FIG. 38A shows this state. The insulating film 63 forms a mandrel of the spacer film 64. Further, as shown in FIG. 38B, the insulating film 63 is removed.

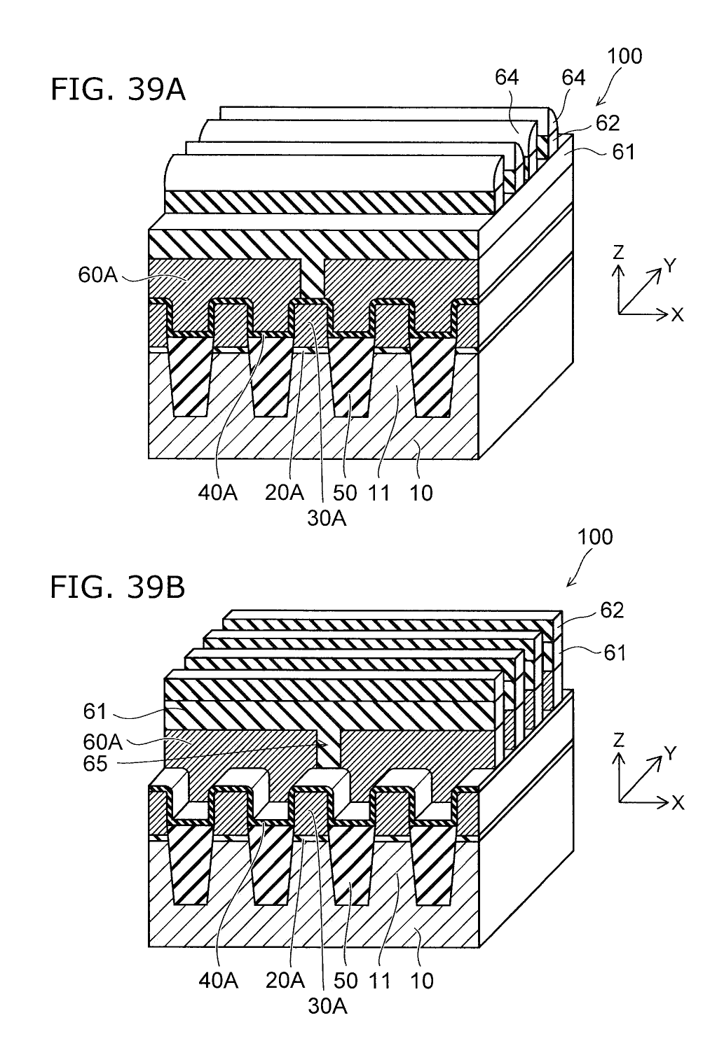

Next, as shown in FIG. 39A, the spacer film 64 is used as a mask to perform RIE processing on the insulating film 62. Thereby, the insulating film 62 is separated in the Y-direction. The insulating films 62 extend in the X-direction.

Next, as shown in FIG. 39B, the insulating film 62 is used as a mask to perform RIE processing on the insulating film 61 and the control gate electrode layer 60A on the lower side of the insulating film 62. Thereby, the control gate electrode layers 60A are further separated in the Y-direction. Thereby, a plurality of control gate electrodes 60 extending in the X-direction are formed. Also the gate insulating film 40A and the charge storage layer 30A on the lower side of the control gate electrode 60 are separated in the Y-direction. Thereby, the charge storage layer 30A in a columnar shape is formed.

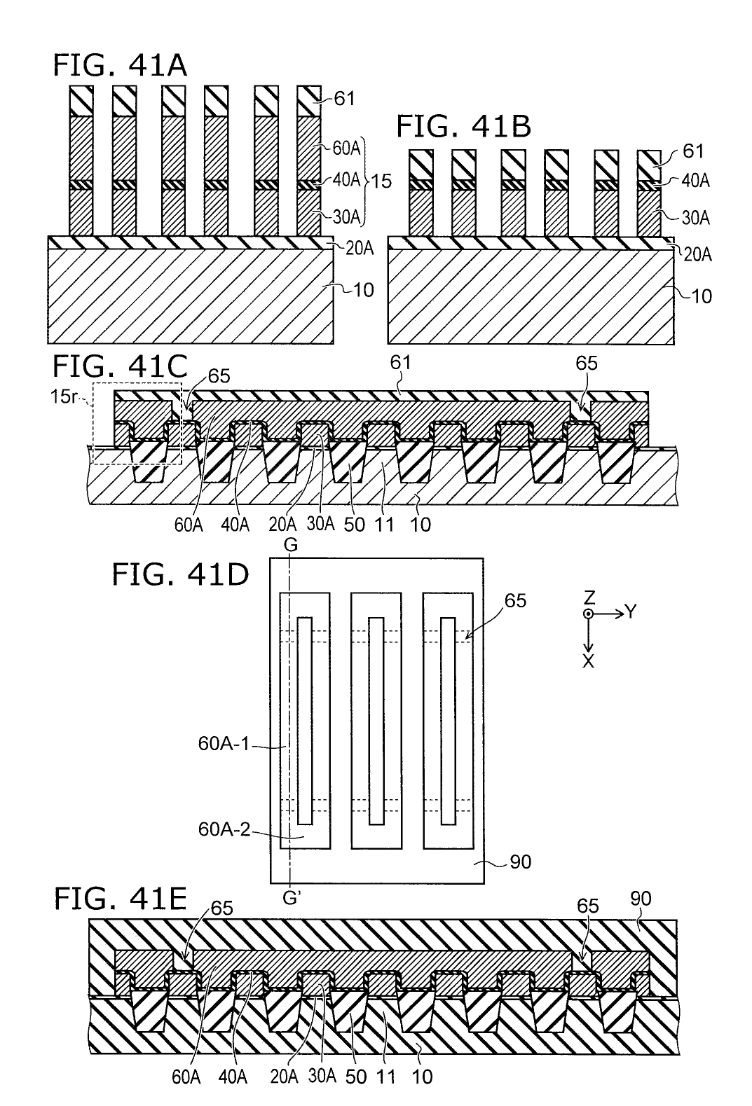

The state where the control gate electrodes 60 extend in the X-direction is shown again in FIG. 40 and FIG. 41A to FIG. 41C.

FIG. 40 is an example of a schematic plan view showing the state where the plurality of control gate electrodes extend in the X-direction.

FIG. 41A to FIG. 41C are examples of schematic cross-sectional views showing the state where the control gate electrodes 60 extend in the X-direction. FIG. 41A is a cross section taken along line E-E′ of FIG. 40, FIG. 41B is a cross section taken along line F-F′ of FIG. 40, and FIG. 41C is a cross section taken along line G-G′ of FIG. 40.

In the second embodiment, after the cut portion 65 is formed, the control gate electrode layer 60A is separated in the Y-direction to form the control gate electrodes 60A extending in the X-direction. In other words, in the second embodiment, adjacent control gate electrodes 60A are not electrically connected via a loop portion 15r, nor is the process of removing the loop portion 15r needed after the control gate electrodes 60A are formed. In the second embodiment, since the process of removing the loop portion 15r after the control gate electrodes 60A are formed is not needed, the collapse of memory cells and the increase in the width of the end portion 15e of the stacked body 15 mentioned earlierare suppressed.

Here, the memory cell region according to the second embodiment includes an element isolation region 50 separatong the semiconductor layer 10 in the Y-direction and extending in the X-direction. The charge storage layer 30A is disposed above the semiconductor layer 10 via the insulating film 20A. The gate insulating film 40A continuously extending in the X-direction is disposed on the upper surface and the side surface of the element isolation region 50 and the charge storage layer 30A. The insulating film 61 embedded into the cut portion 65 is formed on the gate insulating film 40A. The control gate electrode layer 60A is disposed on the gate insulating film 40A.

After that, the insulating films 61 and 62 may be removed as necessary. Further, the interlayer insulating film 90 is formed on the control gate electrodes 60 in such a manner that a space 98 remains between control gate electrodes 60 (not shown) as shown FIG. 41D. Interconnections, contacts, elements, etc. may be formed on the interlayer insulating film 90.

In FIG. 41D, the control gate electrode layer 60A have two first portions 60A-1 extending in the X-direction and two second portions 61A-2 extending in the Y-direction and shorter than the first portion 60A-1. The insulating films 90-C are disposed at two positions of respective first portions 61A-1, namely, disposed at four positions in two of the first portions 60A-1. The insulating films 90-C are arranged in straight in the Y-direction.

The insulating film 90-C is disposed at a position nearer to the second portion 60A-2 than the center of the first portion 60A-1.

The insulating film 90-C is disposed immediately above the charge storage layer 30A via the gate insulating film 40A. The insulating film 90 is formed on the gate control electrode 60A, and the insulating film 90 is connected to the insulating film 90-C embedded in the cut portion 65. The insulating films 90-C contacts to the gate insulating film 40A at the cut portion 65 in FIG. 40E being a cross section taken along line G-G′ of FIG. 40D. That is, it is said that the insulating film 90 is formed on the control gate electrode layer 60A and has insulating films including the same material as the insulating film 90-C, and the insulating films 90 are connected to upper surfaces of the two insulating films 90-C disposed in cut portions 65.

Here, the area of the cut portion 65 may be set smaller than the area of the loop portion 15r. Thus, the flatness is better in the method in which the interlayer insulating film 90 is formed in the cut portion 65 than in the method in which the loop portion 15r is removed and then the interlayer insulating film 90 is buried in the region of the loop portion 15r. Thereby, when lithography is performed on the upper side of the interlayer insulating film 90, defocusing in exposure in the lithography is suppressed more, for example.

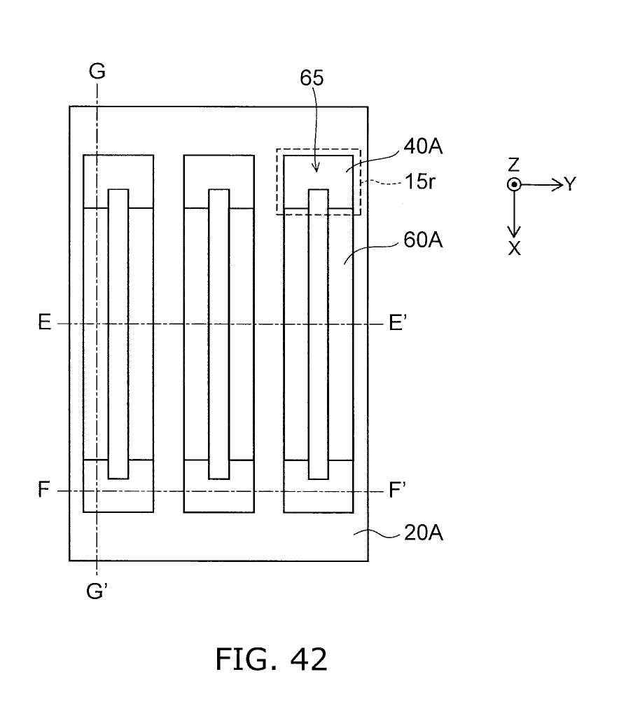

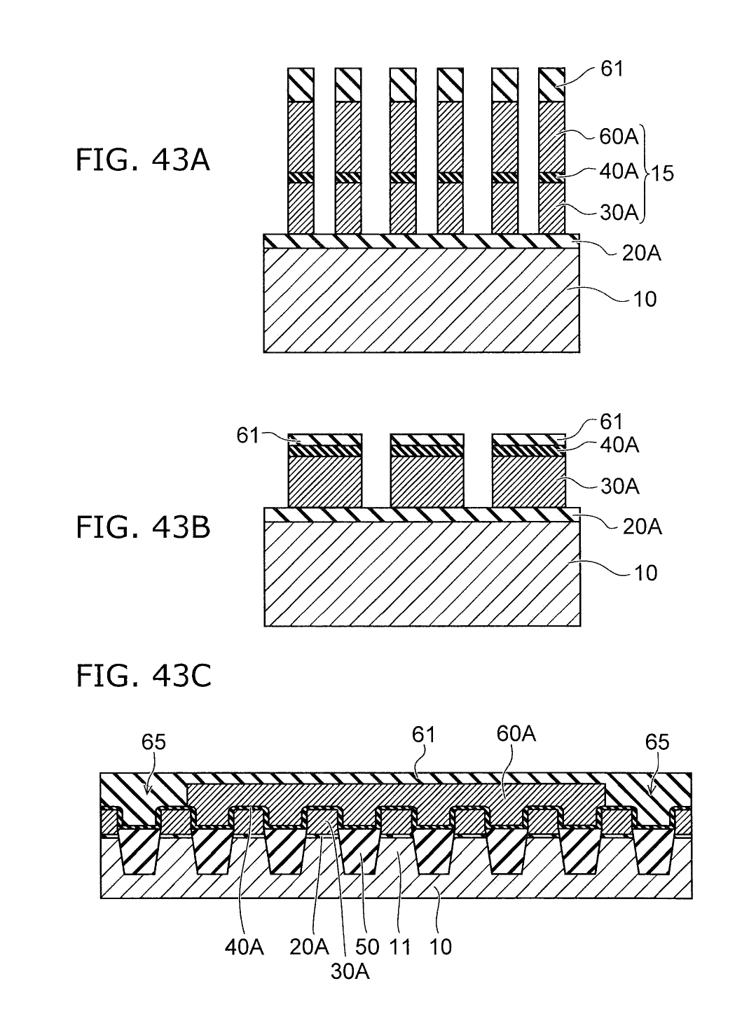

The cut portion 65 may be formed in all of the loop portion 15r. FIG. 42 and FIG. 43A to FIG. 43C show a state where the cut portion 65 is formed in the loop portion 15r.

FIG. 42 is an example of a schematic plan view showing the state where the plurality of control gate electrodes extend in the X-direction.

FIG. 43A to FIG. 43C are examples of schematic cross-sectional views showing the state where the control gate electrodes 60 extend in the X-direction. FIG. 43A is a cross section taken along line E-E′ of FIG. 42, FIG. 43B is a cross section taken along line F-F′ of FIG. 42, and FIG. 43C is a cross section taken along line G-G′ of FIG. 42.

In the process shown in FIGS. 35A to 35C, the trench tr is formed in a portion corresponding to a loop portion 15r, for example. The insulating film 61 is buried in the trench tr, and the cut portion 65 is formed. Then, the control gate electrode layer 60A is separated in the Y-direction to form the control gate electrodes 60A extending in the X-direction. Also by such a method, adjacent control gate electrodes 60A are not electrically connected via a loop portion, nor is the process of removing the loop portion 15r needed after the control gate electrodes 60A are formed. Furthermore, since the process of removing the loop portion 15r after the control gate electrodes 60A are formed is not needed, the probability of collapsing of memory cell is less and the increase in the width of the end portion 15e of the stacked body 15 described above are suppressed.

In the nonvolatile semiconductor memory device, the loop portion 15r forms an unused region. By disposing the cut portion 65 in the loop portion 15r as shown in FIG. 42 and FIGS. 43A to 43C, the nonvolatile semiconductor memory device can be downsized.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

The term “on” in “a portion A is provided on a portion B” refers to the case where the portion A is provided on the portion B such that the portion A is in contact with the portion B and the case where the portion A is provided above the portion B such that the portion A is not in contact with the portion B.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device comprising:
a semiconductor layer;
element regions separated the semiconductor layer in a first direction, the element regions extending in a second direction crossing the first direction; and
a memory cell including a first gate insulating film, a charge storage layer, a second gate insulating film, and a control gate electrode provided above the element regions,
a peripheral region including a resistance element including
a resistance element layer provided above the semiconductor layer via a first insulating film,
a dummy layer provided on a part of the resistance element layer via a second insulating film,
a third insulating film provided on the resistance element layer at a first distance from the dummy layer,
a fourth insulating film provided on the semiconductor layer at a second distance from the resistance element layer, and
a contact piercing the third insulating film, and connected to the resistance element layer,
the first distance being shorter than the second distance.

2. The device according to claim 1, wherein a material of the third insulating film and a material of the fourth insulating film are the same.

3. The device according to claim 1, wherein the second insulating film is provided between the resistance element layer and the third insulating film, and the contact pierces the second insulating film and the third insulating film to be connected to the resistance element layer.

4. The device according to claim 1, further comprising a fifth insulating film between the second insulating film and the third insulating film,
the fifth insulating film being in contact with a side surfacel of the dummy layer.

5. The device according to claim 4, wherein the contact pierces the fifth insulating film, the third insulating film, and the second insulating film to be connected to the resistance element layer.

6. The nonvolatile semiconductor memory device according to claim 4, wherein a thickness of a portion of the fifth insulating film being in contact with the side surface of the dummy layer is the first distance.

7. The device according to claim 1, wherein the fourth insulating film is in contact with a side wall of the first insulating film.

8. A method for manufacturing a nonvolatile semiconductor memory device including a memory cell region and a peripheral region provided outside the memory cell region, the method comprising:
in the memory cell region,
forming element regions separating a semiconductor layer in a first direction and extending the semiconductor layer in a second direction crossing the first direction, a first gate insulating film provided above the element regions, charge storage layers provided above the first gate insulating film and extending in the second direction, a second gate insulating film provided on the charge storage layers and on at least a part of a side surface of the charge storage layers, and a control gate electrode layer provided on the second gate insulating film;
in the peripheral region,
forming a resistance element layer above the semiconductor layer via a first insulating film and forming a dummy layer on the resistance element layer via a second insulating film;
in the memory cell region,
separating the control gate electrode layer in the second direction to form control gate electrodes extending in the first direction;
in the peripheral region,
processing the resistance element layer, the second insulating film, and the dummy layer to have a first length on the semiconductor layer;
in the memory cell region,
forming a sacrifice film extending in the first direction between the control gate electrodes;
in the peripheral region,
forming a side wall film on a side surface of the resistance element layer, the second insulating film, and the dummy layer;
in the peripheral region,
removing a portion of the dummy layer provided on the resistance element layer to make a length of the dummy layer a second length shorter than the first length;
in the peripheral region,
forming a third insulating film on the resistance element layer where the dummy layer is not provided at a first distance from the dummy layer and forming a fourth insulating film on the semiconductor layer at a second distance from the resistance element layer; and
forming a contact extending in a direction from the resistance element layer to the dummy layer, piercing the third insulating film, and connected to the resistance element layer.

9. The method according to claim 8, further comprising, in the peripheral region, removing the sacrifice film from between the control gate electrodes after the forming the fourth insulating film.

10. A method for manufacturing a nonvolatile semiconductor memory device comprising:
forming element regions separating a semiconductor layer in a first direction and extending the semiconductor layer in a second direction crossing the first direction, a first gate insulating film provided above the element regions, charge storage layers provided above the first gate insulating film and extending in the second direction, and a second gate insulating film provided on the charge storage layers and on at least a part of a side surface of the charge storage layers, and a control gate electrode layer on the second gate insulating film;
forming a trench separating the control gate electrode layer in the first direction and burying an insulating film in the trench; and
separating the control gate electrode layers in the second direction to form control gate electrodes extending in the first direction.

11. The method according to claim 10, further comprising:
in a peripheral region disposed a resistance element,
forming a resistance element layer on the semiconductor layer via a first insulating film and forming a dummy layer on the resistance element layer via a second insulating film simultaneously with the forming the control gate electrode layer; and
removing a portion of the dummy layer provided on the resistance element layer simultaneously with the forming the trench separating the control gate electrode layer in the first direction.

12. A nonvolatile semiconductor memory device comprising:
an element isolation region separating a semiconductor layer in a first direction and extending in a second direction crossing the first direction to forme a element region;
a charge storage layer disposed above the element region;
a first insulating film extending in the second direction and disposed on an upper surface of the charge storage layer; and
a control gate electrode layer formed on the first insulating film, and the control gate electrode layer having two first portions extending in the first direction and two second portions extending in the second direction, and the each of two first portions having two dividing portions, and
second insulating films contacting to a upper surface of the first insulating film at the dividing portions.

13. The device according to claim 12, wherein the dividing portions are arranged linearly in the second direction.

14. The device according to claim 12, wherein the dividing portions are formed at positions nearer to the second portion than a center of the first portion.

15. The device according to claim 12, wherein the dividing portions are disposed immediately above the charge storage layer.

16. The device according to claim 12, wherein further comprising a third insulating film formed above the control gate electrode layer and having a same material as the second insulating films,
the third insulating film contacts each of uppder surfaces of the second insulating film.
